(19) United States
(12) Patent Application Publication
(10) Pub. No.: US 2024/0279574 A1
(43) Pub. Date: Aug. 22, 2024

(54) COMPOSITION AND METHOD FOR TREATING OBJECT TO BE TREATED

(71) Applicant: FUJIFILM Corporation, Tokyo (JP)

(72) Inventors: Moe NARITA, Haibara-gun (JP); Atsushi MIZUTANI, Haibara-gun (JP)

(73) Assignee: FUJIFILM Corporation, Tokyo (JP)

(21) Appl. No.: 18/609,739

(22) Filed: Mar. 19, 2024

Related U.S. Application Data
(63) Continuation of application No. PCT/JP2022/035607, filed on Sep. 26, 2022.

(30) Foreign Application Priority Data
Sep. 30, 2021 (JP) 2021-160592

(51) Int. Cl. C11D 7/08; C11D 7/32; C11D 7/50

(52) U.S. Cl. CPC C11D 7/08; C11D 7/3209; C11D 7/50; C11D 2111/22

(57) ABSTRACT

An object of the present invention is to provide a composition having excellent ruthenium removability with respect to tungsten in a case of being applied to an object to be treated containing tungsten and ruthenium. The composition according to an embodiment of the present invention includes: periodic acid or a salt thereof, a quaternary ammonium salt; a resin containing a nitrogen atom; and a solvent.

### CROSS-REFERENCE TO RELATED APPLICATIONS

This application is a Continuation of PCT International Application No. PCT/JP2022/035607 filed on Sep. 26, 2022, which claims priority under 35 U.S.C. § 119(a) to Japanese Patent Application No. 2021-160592 filed on Sep. 30, 2021. The above applications are hereby expressly incorporated by reference, in their entirety, into the present application.

### BACKGROUND OF THE INVENTION

### 1. Field of the Invention

The present invention relates to a composition and a method for treating an object to be treated.

### 2. Description of the Related Art

When a circuit and an element are formed, it is general to perform an etching process using a chemical liquid.

At this time, since a plurality of materials may be present on the substrate, it is desirable that the chemical liquid used for etching is a chemical liquid capable of selectively removing only a specific material.

In recent years, ruthenium (hereinafter, also simply referred to as “Ru”) has been used as an electrode material, a wiring material, and the like of a semiconductor element, and it is necessary to perform a process of removing Ru present in unnecessary portions as in other wiring materials. A chemical liquid is often used in the process of removing Ru.

For example, JP2020-087945A discloses a removal composition suitable for removing Ru from a substrate. More specifically, JP2020-087945A discloses a removal composition containing water, periodic acid, tetramethylammonium hydroxide, and the like.

### SUMMARY OF THE INVENTION

While Ru is used as a wiring material and the like, tungsten (hereinafter, also simply referred to as “W”) is also used as a wiring material and the like in some cases. Here, in a case where both Ru and W are present on a substrate such as a semiconductor, there is a need to selectively remove only Ru without corroding W.

The present inventors have studied the removal composition described in JP2020-087945A, and have found that the removal composition does not have sufficient ability to selectively remove Ru with respect to W and needs to be further improved.

Therefore, an object of the present invention is to provide a composition having excellent removability of Ru with respect to W in a case of being applied to an object to be treated containing W and Ru.

Another object of the present invention is to provide a method for treating an object to be treated using the composition.

As a result of intensive studies to solve the above-described problems, the present inventors have completed the present invention. That is, the present inventors have found that the above-described problems can be solved by the following configurations.

[1] A composition comprising:
periodic acid or a salt thereof;
a quaternary ammonium salt;
a resin containing a nitrogen atom; and
a solvent.

[2] The composition according to [1], wherein the composition is used for an object to be treated containing ruthenium.

[3] The composition according to [1] or [2], wherein the resin has a repeating unit containing a nitrogen atom.

[4] The composition according to any one of [1] to [3], wherein the resin has a repeating unit selected from the group consisting of a repeating unit represented by Formula (1) described later, a repeating unit represented by Formula (2) described later, a repeating unit represented by Formula (3) described later, and a repeating unit represented by Formula (4) described later.

[5] The composition according to [4], wherein the resin has a repeating unit selected from the group consisting of the repeating unit represented by Formula (1) described later, the repeating unit represented by Formula (2) described later, and the repeating unit represented by Formula (3) described later.

[6] The composition according to [4], wherein the resin has the repeating unit represented by Formula (1) described later.

[7] The composition according to [4], wherein the resin has the repeating unit represented by Formula (3) described later.

[8] The composition according to any one of [1] to [7], wherein the resin has a repeating unit having a quaternary ammonium salt structure.

[9] The composition according to any one of [1] to [8], wherein the resin has a nitrogen
atom in a main chain.

[10] The composition according to any one of [1] to [9], wherein the periodic acid or the salt thereof includes at least one selected from the group consisting of orthoperiodic acid, metaperiodic acid, and salts thereof.

[11] The composition according to any one of [1] to [10], wherein the quaternary ammonium salt includes at least one selected from the group consisting of a tetramethylammonium salt, a tetraethyl ammonium salt, a tetrabutylammonium salt, an ethyltrimethylammonium salt, a triethylmethylammonium salt, a diethyldimethylammonium salt, a tributylmethylammonium salt, a dimethyldipropylammonium salt, a benzyltrimethylammonium salt, a benzyltriethylammonium salt, a (2-hydroxyethyl)trimethylammonium salt, and a triethyl(2-hydroxyethyl)ammonium salt.

[12] The composition according to any one of [1] to [11], wherein the composition has a pH of 3.0 to 10.0.

[13] The composition according to any one of [1] to [12], wherein a weight average molecular weight of the resin is 1,000 to 200,000.

[14] The composition according to any one of [1] to [13], wherein a content of the resin is 1 to 1,000 ppm by mass with respect to a total mass of the composition.

[15] The composition according to any one of [1] to [14], wherein the composition does not substantially contain insoluble particles.

[16] A method for treating an object to be treated, comprising bringing an object to be treated containing ruthenium and tungsten into contact with the composition according to any one of [1] to [15] to remove the ruthenium.

According to an aspect of the present invention, it is possible to provide a composition having excellent removability of Ru with respect to W in a case of being applied to an object to be treated containing W and Ru.

In addition, according to an aspect of the present invention, it is also possible to provide a method for treating an object to be treated containing W and Ru.

### BRIEF DESCRIPTION OF THE DRAWINGS

FIG. 1 is a schematic cross-sectional view of an upper portion showing an example of an object to be treated which is used in step A1.

FIG. 2 is a schematic cross-sectional view of an upper portion showing an example after performing step A1 on the object to be treated, shown in FIG. 1.

FIG. 3 is a schematic cross-sectional view of an upper portion showing another example of the object to be treated which is used in step A1.

FIG. 4 is a schematic cross-sectional view of an upper portion showing an example after performing step A1 on the object to be treated, shown in FIG. 3.

FIG. 5 is a schematic view showing an example of an object to be treated which is used in step A2.

FIG. 6 is a schematic cross-sectional view showing an example of an object to be treated which is used in step A4.

FIG. 7 is a schematic cross-sectional view showing an example of an object to be treated before dry etching.

FIG. 8 is a schematic cross-sectional view showing another example of the object to be treated, used in step A4.

FIG. 9 is a schematic cross-sectional view showing an example of an object to be treated before the formation of a Ru-containing film.

FIG. 10 is a schematic cross-sectional view showing an example of an object to be treated which is used in step A6.

### DESCRIPTION OF THE PREFERRED EMBODIMENTS

Hereinafter, the present invention will be described in detail.

The configuration requirements described below may be described based on representative embodiments of the present invention, but the present invention is not limited to such embodiments.

Hereinafter, the meaning of each description in the present specification is shown.

In the present specification, a numerical range represented by using “to” means a range including numerical values described before and after “to” as a lower limit value and an upper limit value.

In the present specification, “ppm” is an abbreviation for “parts per million” and means 10⁻⁶. In addition, “ppb” is an abbreviation for “parts per billion” and means 10⁻⁹. “ppt” is an abbreviation for “parts per trillion” and means 10⁻¹² In the present specification, in a case where two or more types of certain components are present, the “content” of the components means the total content of the two or more types of components.

Unless otherwise specified, the term “exposure” includes exposure with far ultraviolet rays typified by those emitted from a mercury lamp and an excimer laser, X-rays, or EUV light, and drawing with corpuscular beams such as electron beams or ion beams.

The term “preparation” is meant to encompass procuring a predetermined material by purchases or the like, in addition to preparing a specific material by synthesis, blending, or the like.

In the present specification, unless particularly limited, the compound as described herein may include structural isomers (compounds having the same number of atoms but different structures), optical isomers, and isotopes. The compound as described herein may also include one type or a plurality of types of isomers and isotopes.

In the present specification, the dry etching residue is a by-product generated by performing dry etching (for example, plasma etching), and refers to, for example, an organic substance residue derived from a photoresist, a Si-containing residue, and a metal-containing residue (for example, a transition metal-containing residue).

In the present specification, as for the bonding direction of a divalent group (for example, —COO—), unless otherwise specified, when Y in a compound represented by “X—Y—Z” is —COO—, the compound may be any of “X—O—CO—Z” and “X—CO—O—Z”.

In the present specification, unless otherwise specified, the weight-average molecular weight (Mw) and the number-average molecular weight (Mn) are values measured by gel permeation chromatography (GPC) analysis using TSKgel GMHxL, TSKgel G4000HxL, or TSKgel G2000HxL (all of which are trade names manufactured by Tosoh Corporation) as a column, tetrahydrofuran (THF) as an eluent, a differential refractometer as a detector, and polystyrene as a standard substance, and are values converted using polystyrene as the standard substance.

In the present specification, unless otherwise specified, the molecular weight of a compound having a molecular weight distribution is the weight average molecular weight (Mw).

### <Composition>

The composition according to an embodiment of the present invention contains periodic acid or a salt thereof, a quaternary ammonium salt, a resin containing a nitrogen atom, and a solvent.

In a case where the composition according to an embodiment of the present invention has the above-described configuration, the mechanism by which the composition exhibits excellent removability of Ru with respect to W in a case of being applied to an object to be treated including W and Ru is not necessarily clear, but the present inventors presume as follows.

When the composition contains periodic acid or a salt thereof and a solvent, the composition can exhibit removing performance (etching performance) for both W and Ru, but when the composition contains a resin containing a nitrogen atom, etching of W is mainly suppressed, and thus Ru can be selectively etched. Further, it is considered that when the composition contains a quaternary ammonium salt, dissolution of Ru is promoted, and thus Ru can be selectively etched.

Hereinafter, components which may be contained in the composition will be described in detail.

Hereinafter, the fact that excellent removability of Ru with respect to W is achieved when the composition is applied to an object to be treated containing W and Ru is also referred to as “excellent in Ru/W selectivity”.

[Periodic acid or salt thereof] The composition according to an embodiment of the present invention contains periodic acid or a salt thereof.

Examples of the periodic acid or a salt thereof include orthoperiodic acid (H₅IO₆), metaperiodic acid (HIO₄), and a salt thereof (for example, a sodium salt or a potassium salt thereof).

Among these, orthoperiodic acid, orthoperiodate, or metaperiodic acid is preferable, and orthoperiodic acid is more preferable from the viewpoint of excellent Ru/W selectivity.

The periodic acid or a salt thereof may be used singly or in combination of two or more types thereof.

In addition, the content of the periodic acid or a salt thereof is preferably 0.01 to 15.00 mass %, more preferably 0.10 to 10.00 mass %, and still more preferably 0.10 to 5.00 mass % with respect to the total mass of the composition.

When two or more types of periodic acids or salts thereof are used, the total content of the periodic acids or salts thereof is preferably within the above preferred range.

In the composition, a part of the periodic acid may form a salt structure with a resin containing a nitrogen atom described later.

[Quaternary ammonium salt] The composition according to an embodiment of the present invention contains a quaternary ammonium salt.

The quaternary ammonium salt is a compound composed of a quaternary ammonium cation and an anion. The quaternary ammonium salt is not particularly limited, but preferably includes a quaternary ammonium salt represented by Formula (a).

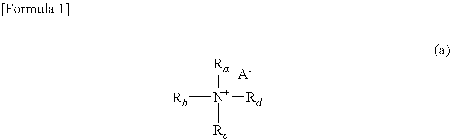

In Formula (a), Rₐ to R_{d} each independently represent an alkyl group which may have a sub stituent.

The alkyl group may be linear or branched, and is preferably linear. The number of carbon atoms of the alkyl group moiety of the alkyl group preferably is 1 to 20, more preferably 1 to 8, and still more preferably 1 to 4. Specific examples of the alkyl group include a methyl group, an ethyl group, a propyl group, a butyl group, a pentyl group, a hexyl group, a heptyl group, an octyl group, a nonyl group, a decyl group, an undecyl group, a dodecyl group, a tridecyl group, a tetradecyl group, a pentadecyl group, and a hexadecyl group.

Examples of the substituent include a hydroxy group and a phenyl group. Examples of the form of the alkyl group having a substituent include a 2-hydroxyethyl group, a 2-hydroxypropyl group, and a benzyl group. In addition, a methylene group constituting the alkyl group may be substituted with a divalent substituent such as —O—.

The total number of carbon atoms contained in the quaternary ammonium salt represented by Formula (a) is not particularly limited, but is preferably 4 to 20 and more preferably 4 to 14.

In addition, two alkyl groups which may have substituents selected from Rₐ to R_{d} may be bonded to each other to form a ring.

In Formula (a), A⁻ represents a monovalent anion.

Examples of the monovalent anion represented by A⁻ include F⁻, Cl⁻, Br⁻, OH⁻, NO₃⁻, CH₃COO⁻, and CH₃CH₂SO₄, and among these, F⁻, Cl⁻, Br⁻, or OH⁻ is preferable, Cl⁻ or OH⁻ is more preferable, and OH⁻ is still more preferable.

Examples of the quaternary ammonium salt represented by Formula (a) include a tetramethylammonium salt, a tetraethyl ammonium salt, a tetrabutylammonium salt, an ethyltrimethylammonium salt, a triethylmethylammonium salt, a diethyldimethylammonium salt, a tributylmethylammonium salt, a dimethyldipropylammonium salt, a dodecyltrimethylammonium salt, a trimethyltetradecylammonium salt, a hexadecyltrimethylammonium salt, a benzyltrimethylammonium salt, a benzyltriethylammonium salt, a (2-hydroxyethyl)trimethylammonium salt (also referred to as “choline”), a triethyl(2-hydroxyethyl)ammonium salt, a diethylbis(2-hydroxyethyl)ammonium salt, an ethyltris(2-hydroxyethyl)ammonium salt, and a tri s(2-hydroxyethyl)methyl ammonium salt.

Among these, from the viewpoint of excellent Ru/W selectivity, the quaternary ammonium salt preferably includes at least one selected from the group consisting of a tetramethylammonium salt, a tetraethyl ammonium salt, a tetrabutylammonium salt, an ethyltrimethylammonium salt, a triethylmethylammonium salt, a diethyldimethylammonium salt, a tributylmethylammonium salt, a dimethyldipropylammonium salt, a benzyltrimethylammonium salt, a benzyltriethylammonium salt, a (2-hydroxyethyl)trimethylammonium salt, and a triethyl(2-hydroxyethyl)ammonium salt.

The anion contained in the above-described salt is preferably F⁻, Cl⁻, Br⁻ or OH⁻, more preferably Cl⁻ or OH⁻, and still more preferably OH⁻.

The quaternary ammonium salt may be used singly or in combination of two or more types thereof.

The total content of the quaternary ammonium salt is preferably 0.01 to 10.00 mass %, more preferably 0.10 to 5.00 mass %, and still more preferably 0.10 to 2.50 mass % with respect to the total mass of the composition.

The molecular weight of the quaternary ammonium salt is preferably 90 to 1,000, more preferably 90 to 500, still more preferably 90 to 300, and particularly preferably 90 to 200.

[Resin containing nitrogen atom] The composition according to an embodiment of the present invention contains a resin containing a nitrogen atom (hereinafter, also referred to as a “nitrogen-containing resin”). The nitrogen-containing resin is a compound different from the quaternary ammonium salt.

The nitrogen-containing resin refers to a resin containing a nitrogen atom in a part of the resin. The resin refers to a compound obtained by polymerizing a monomer and refers to a compound having a weight average molecular weight of 500 or more.

The nitrogen-containing resin may have a nitrogen atom in a part of the resin, but preferably contains a repeating unit having a nitrogen atom (hereinafter, also referred to as a “nitrogen-containing unit”). The nitrogen-containing resin may also contain a repeating unit other than the nitrogen-containing unit (hereinafter, also referred to as “other units”).

### (Nitrogen-Containing Unit)

The form of the nitrogen atom contained in the nitrogen-containing unit is not particularly limited, and the nitrogen atom may be cationized. In addition, in the nitrogen atom contained in the nitrogen-containing unit, all the bonds between the nitrogen atom and the surrounding atoms may be a single bond or may include a double bond or a triple bond.

Examples of the form of the nitrogen atom in the nitrogen-containing unit include structures represented by Formulae (A) to (D).

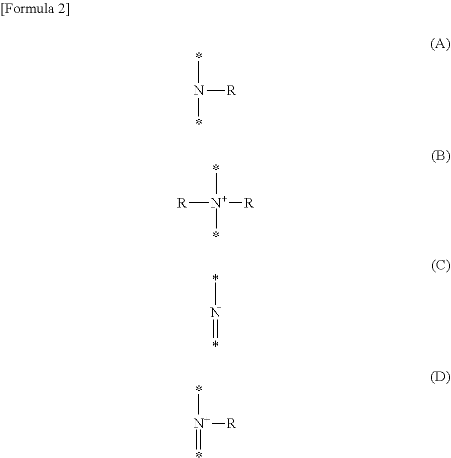

In Formulae (A) to (D), * represents a bonding position.

In Formulae (A), (B), and (D), R each independently represents a hydrogen atom or a monovalent substituent.

Examples of the structure having a structure represented by Formula(A) include a primary amine structure, a secondary amine structure, and a tertiary amine structure. The primary amine structure refers to a structure in which, among three atoms bonded to a nitrogen atom, two atoms are hydrogen atoms and one atom is an atom other than a hydrogen atom (for example, a carbon atom). The secondary amine structure refers to a structure in which, among three atoms bonded to a nitrogen atom, one atom is a hydrogen atom and two atoms are atoms other than a hydrogen atom (for example, carbon atoms). The tertiary amine structure refers to a structure in which three atoms bonded to a nitrogen atom are atoms other than hydrogen atoms (for example, carbon atoms).

Examples of the structure having a structure represented by Formula(B) include a quaternary ammonium salt structure. The quaternary ammonium salt structure refers to a salt in which a nitrogen atom is cationized, four atoms bonded to the nitrogen atom are atoms other than hydrogen atoms (for example, carbon atoms), and these are electrostatically bonded to an anion.

Examples of the structure having a structure represented by Formula (C) include an imine structure and an aromatic imine structure (a nitrogen atom in a pyridine ring, an azole ring, and the like). The imine structure refers to a structure in which a nitrogen atom is bonded to two atoms, the bond between the nitrogen atom and one atom is a single bond, and the bond between the nitrogen atom and the other atom is a double bond.

Examples of the structure having a structure represented by Formula (D) include an iminium salt structure (a salt structure in which a nitrogen atom in an imine structure is cationized and electrostatically bonded to an anion), and an aromatic iminium salt structure (a salt structure in which a nitrogen atom in a pyridine ring, an azole ring or the like is cationized and electrostatically bonded to an anion).

As a form of the nitrogen atom contained in the nitrogen-containing unit, a structure represented by Formula (A) or (B) is preferable from the viewpoint that the Ru/W selectivity is more excellent. Therefore, as a form of the nitrogen atom contained in the nitrogen-containing unit, a primary amine structure, a secondary amine structure, a tertiary amine structure, or a quaternary ammonium salt structure is preferable. From the view point that the Ru/W selectivity is more excellent, the form of the nitrogen atom contained in the nitrogen-containing unit is more preferably a secondary amine structure, a tertiary amine structure, or a quaternary ammonium salt structure, still more preferably a tertiary amine structure or a quaternary ammonium salt structure, and particularly preferably a quaternary ammonium salt structure.

In addition, the nitrogen atom contained in the nitrogen-containing unit may be contained in any of the main chain and the side chain, or may be contained in both the main chain and the side chain. In the present specification, the “main chain” represents a relatively longest binding chain in the molecule of a polymer compound constituting a resin, and the “side chain” represents an atomic group branched from the main chain.

From the viewpoint that the Ru/W selectivity is more excellent, the nitrogen atom contained in the nitrogen-containing unit is preferably at least contained in the main chain.

Examples of a more specific structure of the nitrogen-containing unit include repeating units represented by Formulae (1) to (4).

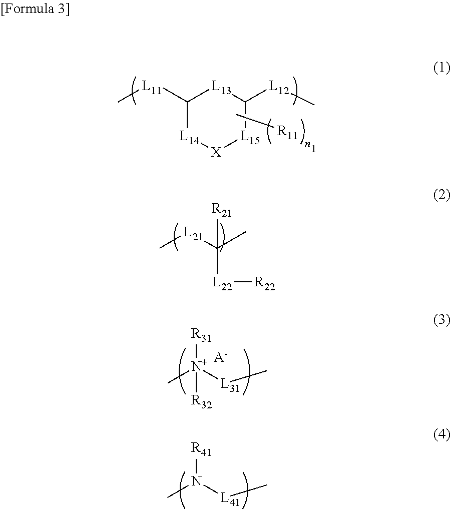

In Formula (1), L₁₁ to L₁₅ each independently represent a single bond or a divalent linking group.

Examples of the divalent linking group represented by L₁₁ and L₁₂ include an alkylene group, a cycloalkylene group, an arylene group, —O—, —S—, —CO—, —COO—, —CONH—, and —SO₂—, and a group in which one or more divalent linking groups selected from the group consisting of —O—, —S—, —CO—, —COO—, —CONH—, and —SO₂— are combined with an alkylene group, a cycloalkylene group, and an arylene group.

The alkylene group may be either linear or branched, and is preferably linear. The number of carbon atoms of the alkylene group is not particularly limited, but is preferably 1 to 10, more preferably 1 to 5, and still more preferably 1 to 3.

The cycloalkylene group may be either monocyclic or polycyclic, and is preferably monocyclic. The number of carbon atoms of the cycloalkylene group is not particularly limited, but is preferably 5 to 12 and more preferably 5 to 8.

The arylene group may be either monocyclic or polycyclic, and is preferably monocyclic. In addition, the arylene group may be a heteroarylene group containing an atom other than a carbon atom as a ring member atom. The number of ring member atoms in the arylene group is not particularly limited, but is preferably 5 to 15 and more preferably 5 to 10.

Among these, L₁₁ and L₁₂ are preferably a single bond, an alkylene group, or a group in which an alkylene group and —SO₂— are combined, and more preferably an alkylene group. More specifically, the alkylene group represented by L₁₁ and L₁₂ is preferably a methylene group, an ethylene group, or a propylene group.

In Formula (1), L₁₃ to L₁₅ each independently represent a single bond or a divalent linking group.

Examples of the divalent linking group represented by L₁₃ to L₁₅ include an alkylene group, —O—, —S—, —CO—, —COO—, —CONH—, and —SO₂—, and a group in which one or more divalent linking groups selected from the group consisting of —O—, —S—, —CO—, —COO—, —CONH—, and —SO₂— are combined with an alkylene group. A preferred form of the alkylene group is as described above.

Among these, L₁₃ is preferably a single bond or an alkylene group, and preferably a single bond. L₁₄ and L₁₅ are preferably a single bond or an alkylene group, and preferably an alkylene group. More specifically, the alkylene group represented by L₁₄ and L₁₅ is preferably a methylene group or an ethylene group.

In Formula (1), X represents a divalent linking group containing a nitrogen atom.

The divalent linking group containing a nitrogen atom is preferably a divalent linking group having a secondary amine structure, a tertiary amine structure, or a quaternary ammonium salt structure. More specifically, the divalent linking group containing a nitrogen atom is preferably a divalent linking group represented by Formula (X1) or a divalent linking group represented by Formula (X2).

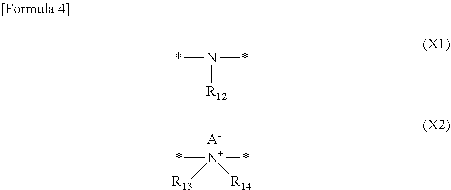

In Formulae (X1) and (X2), * represents a bonding position.

In Formula (X1), R₁₂ represents a hydrogen atom or a monovalent substituent.

Examples of the monovalent substituent represented by Rig include alkyl groups having 1 to 6 carbon atoms, which may have a substituent. The alkyl group may be linear or branched, and is preferably linear. The number of carbon atoms of the alkyl group is preferably 1 to 4 and more preferably 1 to 3. Examples of the substituent of the alkyl group which may have a substituent include a halogen atom, a carboxy group, a sulfo group, and a hydroxy group.

Among these, Rig is preferably a hydrogen atom or an unsubstituted alkyl group, and more preferably an unsubstituted alkyl group. More specifically, the unsubstituted alkyl group is preferably a methyl group, an ethyl group, or a propyl group.

The divalent linking group represented by Formula (X1) may form a salt with acid. Examples of the acid that forms a salt with the divalent linking group represented by Formula (X1) include sulfuric acid, sulfurous acid, iodic acid, hydrogen chloride, hydrogen bromide, nitric acid, amidosulfuric acid, acetic acid, ethylsulfuric acid, and methanesulfonic acid.

In Formula (X2), R₁₃ and R₁₄ each independently represent a monovalent substituent. Examples of the monovalent substituent represented by R₁₃ and R₁₄ include the monovalent substituents represented by Rig, and a preferred form thereof is also the same.

In Formula (X2), A⁻ represents a monovalent anion.

The monovalent anion represented by A⁻ may be an inorganic anion or an organic anion. Examples of the inorganic anion include a hydrogen sulfate ion (HSO₄⁻), a hydrogen sulfite ion (HSO₃⁻), an iodate ion (IO₃⁻), a halogen ion, and a nitrate ion. Examples of the organic anion include an acetate ion, an ethyl sulfate ion, and a methanesulfonate ion. Among these, a halogen ion or an ethyl sulfate ion is preferable. Examples of the halogen ion include a fluoride ion, a chloride ion, a bromide ion, and an iodide ion, and among these, a chloride ion is preferable.

In Formula (1), R₁₁ represents a monovalent substituent. When a plurality of R₁₁ are present, the plurality of R₁₁ each independently represent a monovalent substituent.

Examples of the monovalent substituent represented by R₁₁ include an alkyl group which may have a substituent, a halogen atom, and a hydroxy group. The alkyl group which may have a substituent is the same as the alkyl group which may have a substituent described as the monovalent substituent represented by R₁₂.

In Formula (1), n₁ represents an integer of 0 to 5.

n₁ is preferably 0 to 3, more preferably 0 to 2, still more preferably 0 or 1, and particularly preferably 0.

In Formula (2), L₂₁ represents a divalent linking group.

Examples of the divalent linking group represented by L₂₁ include the divalent linking groups represented by L₁₁ and L₁₂, and a preferred form thereof is also the same. That is, the divalent linking group represented by L₂₁ is preferably an alkylene group, and more preferably a methylene group, an ethylene group, or a propylene group. One or more hydrogen atoms of the alkylene group may be substituted with a monovalent substituent, and examples of the monovalent substituent include a halogen atom and a hydroxy group.

In Formula (2), L₂₂ represents a single bond or a divalent linking group.

Examples of the divalent linking group represented by L₂₂ include the divalent linking groups represented by L₁₁ and L₁₂. As the divalent linking group represented by L₂₂, —COO—, —CONH—, or an alkylene group, or a group in which one or more divalent linking groups selected from the group consisting of —O—, —S—, —CO—, —COO—, —CONH—, and —SO₂— are combined with an alkylene group is preferable.

Among these, L₂₂ is preferably a single bond, an alkylene group, or a —COO-alkylene group, and more preferably an alkylene group.

In Formula (2), R₂₁ represents a hydrogen atom or a monovalent substituent.

Examples of the monovalent substituent represented by R₂₁ include a halogen atom and an alkyl group having 1 to 3 carbon atoms. Among these, R₂₁ is preferably a hydrogen atom or an alkyl group having 1 to 3 carbon atoms.

In Formula (2), R₂₂ represents a monovalent substituent containing a nitrogen atom. The monovalent substituent containing a nitrogen atom, which is represented by R₂₂, is preferably a monovalent substituent having each of the above structures represented by Formulae (A) to (D), and more preferably a monovalent substituent represented by Formulae (B1) to (B8).

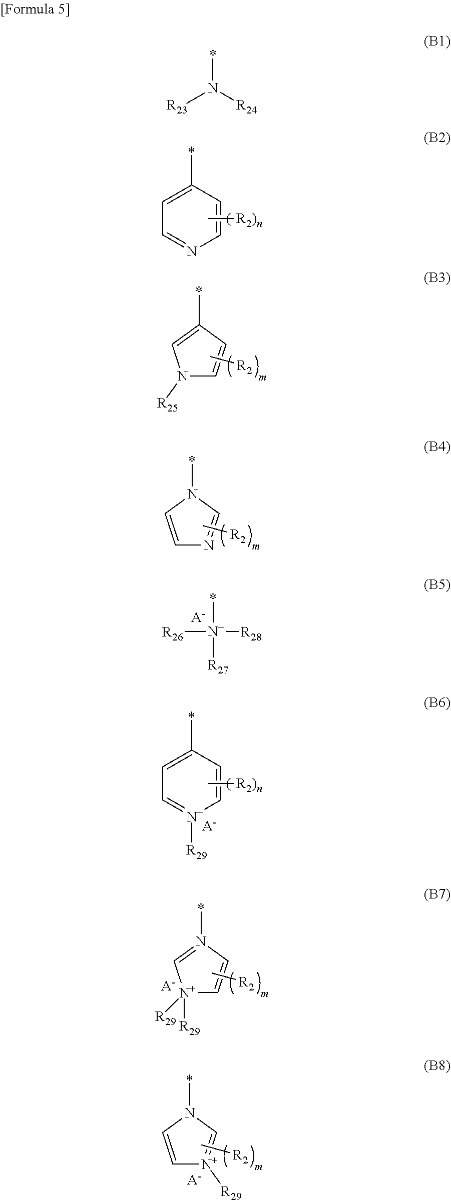

In Formulae (B1) to (B8), * represents a bonding position.

In Formulae (B1) and (B3), R₂₃ to R₂₅ each independently represent a hydrogen atom or a monovalent substituent. Examples of the monovalent substituent represented by R₂₃ to R₂₅ include the monovalent substituents represented by Rig. Among these, R₂₃ to R₂₅ are preferably a hydrogen atom or an unsubstituted alkyl group, and more preferably a hydrogen atom.

In Formulae (B5) to (B8), R₂₆ to R₂₉ each independently represent a monovalent substituent. Examples of the monovalent substituent represented by R₂₆ to R₂₉ include the monovalent substituents represented by Rig. Among these, in Formulae (B5) to (B8), R₂₆ to R₂₉ are preferably an unsubstituted alkyl group.

In Formulae (B2) to (B4) and (B6) to (B8), R₂ represents a monovalent substituent. When a plurality of R₂ are present, the plurality of R₂ each independently represent a monovalent sub stituent.

Examples of the monovalent substituent represented by R₂ include the same groups as the monovalent substituents represented by R₁₁.

In Formulae (B3), (B4), (B7), and (B8), m represents an integer of 0 to 4.

n is preferably 0 to 2, more preferably 0 or 1, and still more preferably 0.

In Formulae (B5) to (B8), A⁻ represents a monovalent anion. Examples of A⁻ in Formulae (B5) to (B8) include the same anions as A⁻ in Formula (X2), and a suitable form thereof is also the same.

The monovalent substituent represented by Formulae (B1) to (B4) may form a salt with acid. Examples of the acid that forms a salt with the monovalent substituent represented by Formulae (B1) to (B4) include acids that form a salt with the divalent linking group represented by Formula (X1).

Among these, as the monovalent substituent containing a nitrogen atom, which is represented by R₂₂, a monovalent substituent represented by Formula (B1), a monovalent substituent represented by Formula (B2), or a monovalent substituent represented by Formula (B5) is preferable, and a monovalent substituent represented by Formula (B1) is preferable.

In Formula (3), L₃₁ represents a divalent linking group.

Examples of the divalent linking group represented by L₃₁ include the divalent linking groups represented by L₁₁ and L₁₂, and an alkylene group is preferable. The number of carbon atoms of the alkylene group is preferably 1 to 10, more preferably 2 to 8, and still more preferably 3 to 6. That is, a propylene group, a butylene group, a pentylene group, or a hexylene group is more preferable. One or more hydrogen atoms of the alkylene group may be substituted with a monovalent substituent, and examples of the monovalent substituent include a halogen atom and a hydroxy group. Examples of the form in which the hydrogen atom of the alkylene group is substituted with a monovalent substituent include —CH₂—CHOH—CH₂— and —CH₂—CH₂— CHOH—CH₂—.

In Formula (3), R₃₁ and R₃₂ each independently represent a monovalent substituent.

Examples of the monovalent substituent represented by R₃₁ and R₃₂ include the monovalent substituents represented by R₁₂, and a preferred form thereof is also the same.

That is, as the monovalent substituent represented by R₃₁ and R₃₂, an unsubstituted alkyl group is preferable, and a methyl group, an ethyl group, or a propyl group is more preferable.

In Formula (3), A⁻ represents a monovalent anion.

Examples of A⁻ in Formula (3) include the same anions as A⁻ in Formula (X2), and a suitable form thereof is also the same.

In Formula (4), L₄₁ represents a divalent linking group.

Examples of the divalent linking group represented by L₄₁ include the divalent linking groups represented by L₁₁ and L₁₂, and an alkylene group is preferable. The number of carbon atoms of the alkylene group is preferably 1 to 10, more preferably 1 to 6, and still more preferably 2 to 4.

In Formula (4), R₄₁ represents a hydrogen atom or a monovalent substituent.

Examples of the monovalent substituent represented by R₄₁ include the monovalent substituents represented by Rig, and a preferred form thereof is also the same. That is, as the monovalent substituent represented by R₄₁, an unsubstituted alkyl group is preferable, and a methyl group, an ethyl group, or a propyl group is more preferable. Among these, a hydrogen atom is preferable.

The repeating units represented by Formulae (1) and (2) are a form having a nitrogen atom in a side chain, and the repeating units represented by Formulae (3) and (4) are a form having a nitrogen atom in the main chain.

As the nitrogen-containing unit contained in the nitrogen-containing resin, among Formulae (1) to (4), a repeating unit represented by Formulae (1) to (3) is preferable, a repeating unit represented by Formula (1) or (3) is more preferable, and a repeating unit represented by Formula (1) is still more preferable from the viewpoint that the Ru/W selectivity is more excellent.

The nitrogen-containing resin may contain a nitrogen-containing unit other than the units described above.

The other nitrogen-containing unit is not particularly limited, and may be a known nitrogen-containing unit. The other nitrogen-containing unit may be a repeating unit in which each of the repeating units represented by Formulae (1) to (4) is crosslinked with a crosslinkable group or a crosslinkable molecule. Examples of the crosslinkable group include an epoxy group and an ethylenically unsaturated group. Examples of the crosslinkable molecule include an isocyanate compound, epichlorohydrin, and formaldehyde.

The nitrogen-containing resin may contain a plurality of types of nitrogen-containing units.

The total content of the nitrogen-containing unit is preferably 5 to 100 mass %, more preferably 20 to 100 mass %, and still more preferably 40 to 100 mass % with respect to the total mass of the nitrogen-containing resin.

The total content of the nitrogen-containing unit is preferably 5 to 100 mol %, more preferably 20 to 100 mol %, and still more preferably 40 to 100 mol % with respect to all the repeating units of the nitrogen-containing resin.

### (Other Units)

Other units which may be contained in the nitrogen-containing resin are not particularly limited, and may be known repeating units.

Examples of such other units include repeating units based on a monomer having an ethylenically unsaturated group. Examples of the monomer having an ethylenically unsaturated group include carboxylic acids having an ethylenically unsaturated group.

Examples of the carboxylic acid having an ethylenically unsaturated group include acrylic acid, methacrylic acid, fumaric acid, cinnamic acid, crotonic acid, itaconic acid, 4-vinylbenzoic acid, maleic acid, maleic anhydride, and a salt thereof. In addition, a condensation compound or an addition compound of the carboxylic acid with a compound having a hydroxy group, a compound having an amino group, and a compound having a glycidyl group may be employed. Examples of the compound include an ester compound of acrylic acid or methacrylic acid with a compound having a hydroxy group, an amide compound of acrylic acid or methacrylic acid with a compound having a primary or secondary amino group, and a half ester compound of maleic acid with a compound having a hydroxy group.

In addition, the other units may also be, for example, a repeating unit based on vinyl acetate, and in the repeating unit based on vinyl acetate, the carboxy group may be eliminated by modification such as hydrolysis. That is, the other units may also be a constitutional unit regarded as being based on vinyl alcohol.

The nitrogen-containing resin may contain a plurality of types of the other units.

The content of the other units is preferably 0 to 95 mass %, more preferably 0 to 80 mass %, and still more preferably 0 to 60 mass % with respect to the total mass of the nitrogen-containing resin.

The content of the nitrogen-containing unit is preferably 5 to 100 mass %, more preferably 20 to 100 mass %, and still more preferably 40 to 100 mass % with respect to all the repeating units of the nitrogen-containing resin.

Specific examples of the nitrogen-containing resin include resins synthesized using each of allylamine and a salt thereof, N-alkylallylamine and a salt thereof, N,N-dialkylallylamine and a salt thereof, trialkylallylammonium salt, diallylamine and a salt thereof, N-alkyldiallylamine and a salt thereof, and N,N-dialkylammonium salt as monomers. Examples of the alkyl group in each of the monomers include a methyl group and an ethyl group.

Examples of the compound that forms a salt with amine include hydrogen chloride (hydrochloric acid), amidosulfuric acid, acetic acid, and ethylsulfuric acid. Examples of the counter anion of the ammonium salt include a chloride ion.

The resin synthesized using diallylamine or the like as a monomer can be a resin containing a repeating unit represented by Formula (1) by polymerization involving cyclization.

Examples of the specific compound name of the resin include polyallylamine, polyallylamine hydrochloride, polydiallylamine, polydiallylamine hydrochloride, and poly(dimethyldiallylammonium chloride), and poly(methyl-ethyl-dimethyl ammonium ethyl sulfate). The resins listed above are resins containing a repeating unit having a cyclic structure.

In addition, the resin synthesized using the N,N-dialkylammonium salt as a monomer can be a resin containing a repeating unit represented by Formula (3) by polymerization.

A specific compound name of the resin includes poly(diallyldimethylammonium chloride). The resins listed above are resins containing a repeating unit having a chain structure.

In addition, copolymers synthesized from two or more types of monomers selected from the above monomers can also be exemplified as the nitrogen-containing resin. Examples of the copolymer include a copolymer synthesized using allylamine and diallylamine as monomers, and a copolymer synthesized using an allylamine salt and a diallylamine salt as monomers.

Further, copolymers synthesized using the above monomers and maleic acid as monomers can also be exemplified as the nitrogen-containing resin. Examples of the copolymer include a copolymer synthesized using diallylamine and maleic acid as monomers.

Specific examples of the nitrogen-containing resin include resins having the skeleton structures represented by Formulae (P-1) to (P-23). In Formulae (P-1) to (P-23), a repeating unit denoted by a reference numeral m is defined as a first repeating unit, and a repeating unit denoted by a reference numeral n is defined as a second repeating unit.

A plurality of repeating units are described in the skeleton structures represented by Formulae (P-1) to (P-23), and the bonding form of the plurality of repeating units is not particularly limited. For example, a plurality of repeating units may be randomly bonded (so-called random copolymer), may be alternately bonded (so-called alternating copolymer), or may be bonded in a block form (so-called block copolymer).

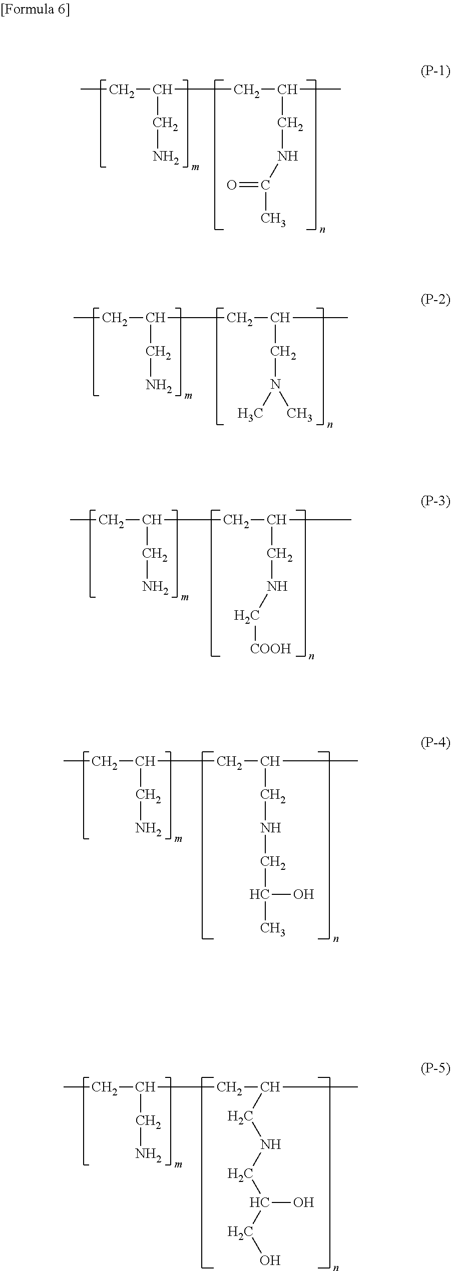

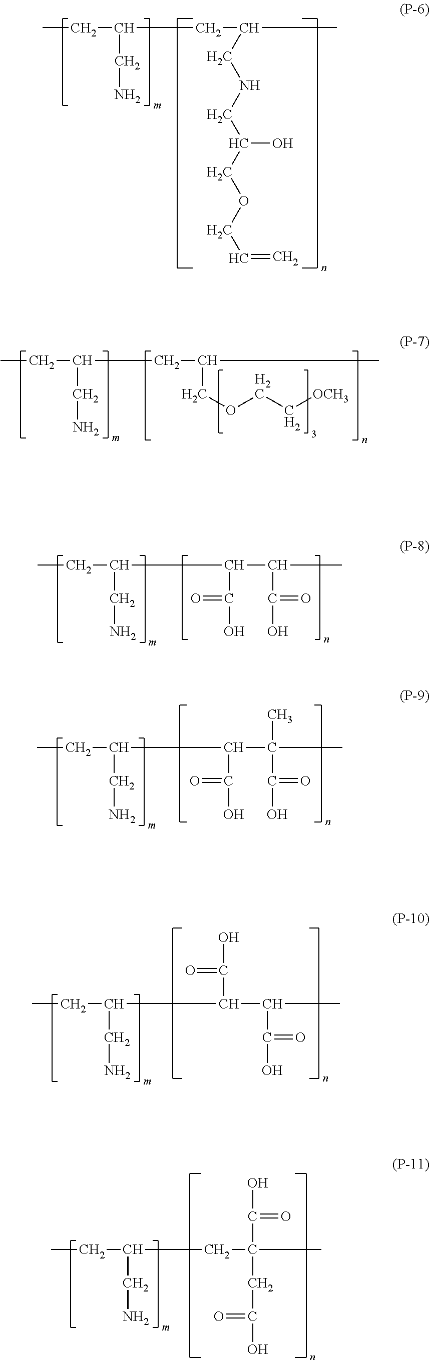

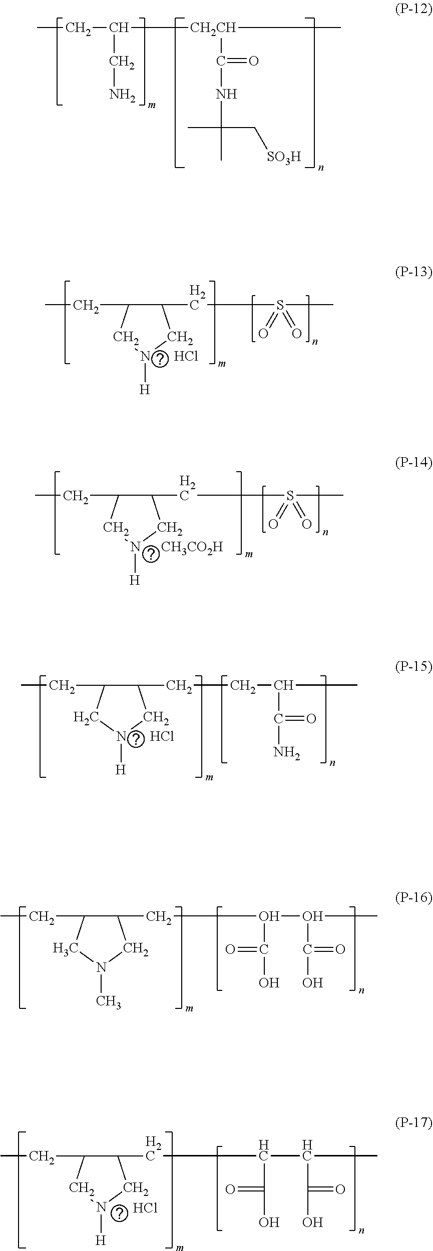

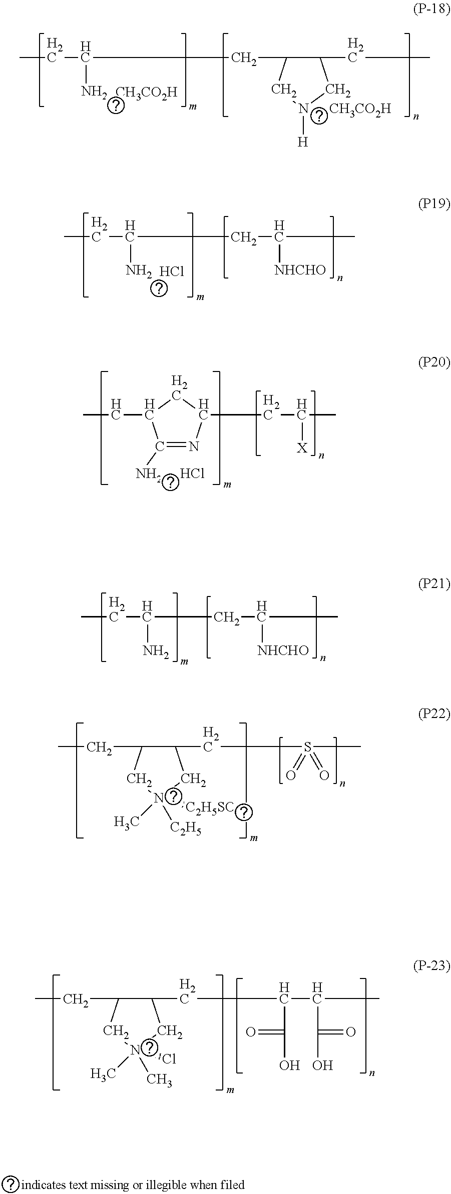

In Formulae (P-1) to (P-23), the ratio (m/n) of the number of moles (m) of the first repeating unit to the number of moles (n) of the second repeating unit is 1/20 to 20/1.

In addition, in Formula (P-7), 1 represents the number of repetitions of the oxyalkylene unit and represents an integer of 1 to 30.

In Formula (P-20), X represents an amide group, a nitrile group, an amino hydrochloride, or a formamide group.

Other specific examples of the nitrogen-containing resin include a resin (poly(2-hydroxypropyldimethylammonium chloride)) formed by condensation polymerization of dimethylamine and epichlorohydrin. The resin formed by condensation polymerization of dimethylamine and epichlorohydrin is a resin containing the repeating unit represented by Formula (3).

In addition, other specific examples of the nitrogen-containing resin include polyethyleneimine obtained by ring-opening polymerization of ethyleneimine. Examples of the polyethyleneimine include linear polyethyleneimine, branched polyethyleneimine, and dendrimer polyethyleneimine. In a case where the polyethyleneimine is linear polyethyleneimine, the polyethyleneimine has a repeating unit represented by Formula (4). Examples of the branched polyethyleneimine include resins containing the units represented by Formulae (4-a), (4-b) and (4-c) below. * and ** in each formula represent a bonding position, and * and ** are bonded to each other.

Examples of the dendrimer polyethyleneimine include resins containing the units represented by Formulae (4-a) and (4-c) below.

* and ** in each formula represent a bonding position, and * and ** are bonded to each other.

The terminals of the resin are **-CH₂—CH₂—NH₂.

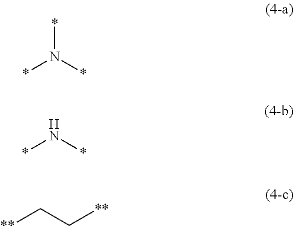

In addition, examples of the known nitrogen-containing resin include the nitrogen-containing resins described in paragraphs [0036] to [0071] of JP1999-255841A (JP-H11-255841A), paragraphs [0040] to [0088] of JP2000-063435A, paragraphs [0025] to [0039] of JP2001-106714A, paragraphs [0062] to [0065] of JP2004-27162A, paragraphs [0068] to [0084] of JP2004-115675A, paragraphs [0051] to [0055] of JP2005-002196A, paragraphs [0097] to [0111] of JP2005-097636A, paragraphs [0026] and [0027] of JP2015-166463A, paragraphs [0037] to [0048] of JP2017-075243A, and paragraphs [0062] to [0069] of JP2021-021020A.

As the nitrogen-containing resin, commercially available products can also be used.

Examples of the commercially available product of the nitrogen-containing resin include PAA-HCL-01 (“PAA” is a registered trademark, and the same applies hereinafter) manufactured by Nittobo Medical Co., Ltd., PAA-HCL-03, PAA-HCL-05, PAA-SA, PAA-01, PAA-03, PAA-05, PAA-08, PAA-15C, PAA-25, PAA-D19A, PAA-D11, PAA-1123, PAA-U5000, PAA-U7030, PAA-N5000, PAS-21CL, PAS-21, PAS-M-1L, PAS-M-1, PAS-M-1A, PAS-H-1L, PAS-H-5L, PAS-H1OL, PAS-24, PAS-92, PAS-92A, PAS-2401, PAS-A-1, PAS-A 5, PAS-2141CL, PAS-2223, PAS-880, PAA-1151, PAS-410L, PAS-410SA, PAS-2251, PAS-84, and PAS-2351.

Examples of the commercially available product of the nitrogen-containing resin other than those described above include Catiomaster (registered trademark) PD series (PD-7 and PD-30), Catiomaster (registered trademark) series (PE-30, EPA-SKO1, and PAE-01) manufactured by Yokkaichi Chemical Co., Ltd., Unisense (registered trade mark) series manufactured by Senka Corporation (KHE100L, KHE107L, KHE1000L, FPA100L, FPA101L, FPA1000L, FCA1003L, FCA1001L, and KCA100L), and ACRIT (registered trademark) series manufactured by Taisei Fine Chemical Co,. Ltd. (1SX-1055F, 1SX-6000, and 1WX-1020).

The weight average molecular weight of the nitrogen-containing resin is preferably 1,000 or more and more preferably 1,500 or more. The upper limit of the weight average molecular weight of the nitrogen-containing resin is not particularly limited, but is 500,000 or less, preferably 200,000 or less, more preferably 20,000 or less, and still more preferably 8,000 or less.

The nitrogen-containing resin may be used singly or in combination of two or more types thereof.

The content of the nitrogen-containing resin is preferably 0.1 to 1,500 ppm by mass, more preferably 1 to 1,000 ppm by mass, still more preferably 1 to 500 ppm by mass, particularly preferably 1 to 200 ppm by mass, and most preferably 5 to 200 ppm by mass with respect to the total mass of the composition.

When two or more types of nitrogen-containing resins are used, the total content of the nitrogen-containing resins is preferably within the above preferred range.

The mass ratio of the content of the periodic acid or a salt thereof to the content of the nitrogen-containing resin is preferably 5 to 150,000, more preferably 5 to 20,000, still more preferably 10 to 20,000, particularly preferably 30 to 10,000, and most preferably 50 to 2,000.

### [Solvent]

The composition according to an embodiment of the present invention contains a solvent.

Examples of the solvent include water and an organic solvent, and water is preferable.

As the water, water subjected to purification treatment, such as distilled water, ion exchange water, and ultrapure water is preferable, and ultrapure water used for producing a semiconductor is more preferable. Water contained in the composition may contain a trace amount of components that are unavoidably mixed in.

The content of water is preferably 50 mass % or more, more preferably 65 mass % or more, and still more preferably 75 mass % or more with respect to the total mass of the composition. The upper limit is not particularly limited, but is preferably 99.999 mass % or less and more preferably 99.9 mass % or less with respect to the total mass of the composition.

As the organic solvent, a water-soluble organic solvent is preferable. The water-soluble organic solvent refers to an organic solvent that can be mixed with water at any proportion. Examples of the water-soluble organic solvent include an ether-based solvent, an alcohol-based solvent, a ketone-based solvent, an amide-based solvent, a sulfur-containing solvent, and a lactone-based solvent.

Examples of the ether-based solvent include diethyl ether, diisopropyl ether, dibutyl ether, t-butyl methyl ether, cyclohexylmethyl ether, tetrahydrofuran, diethylene glycol, dipropylene glycol, triethylene glycol, polyethylene glycol, alkylene glycol monoalkyl ether (ethylene glycol monomethyl ether, ethylene glycol monobutyl ether, propylene glycol monomethyl ether, diethylene glycol monomethyl ether, dipropylene glycol monomethyl ether, tripropylene glycol monomethyl ether, and diethylene glycol monobutyl ether), alkylene glycol dialkyl ether (diethylene glycol diethyl ether, diethylene glycol dipropyl ether, diethylene glycol dibutyl ether, triethylene glycol diethyl ether, tetraethylene glycol dimethyl ether, tetraethylene glycol diethyl ether, ethylene glycol dimethyl ether, diethylene glycol dimethyl ether, and triethylene glycol dimethyl ether).

The number of carbon atoms of the ether-based solvent is preferably 3 to 16, more preferably 4 to 14, and still more preferably 6 to 12.

Examples of the alcohol-based solvent include methanol, ethanol, 1-propanol, 2-propanol, 1-butanol, 2-butanol, ethylene glycol, propylene glycol, glycerin, 1,6-hexanediol, cyclohexanediol, sorbitol, xylitol, 2-methyl-2,4-pentanediol, 1,3-butanediol, and 1,4-butanediol.

The number of carbon atoms of the alcohol-based solvent is preferably 1 to 8 and more preferably 1 to 4.

Examples of the amide-based solvent include formamide, monomethyl formamide, dimethylformamide, acetamide, monomethylacetamide, dimethylacetamide, monoethylacetamide, diethylacetamide, and N-methylpyrrolidone.

Examples of the ketone-based solvent include acetone, methyl ethyl ketone, methyl isobutyl ketone, and cyclohexanone.

Examples of the sulfur-containing solvent include dimethyl sulfone, dimethyl sulfoxide, and sulfolane.

Examples of the lactone-based solvent include y-butyrolactone and 6-valerolactone.

The organic solvent may be used singly or in combination of two or more types thereof.

The content of the organic solvent is preferably 0.1 to 10 mass % with respect to the total mass of the composition.

When two or more types of organic solvents are used, the total content of two or more types of the organic solvents is preferably within the above range.

### [Optional Components]

The composition may contain optional components other than the components described above.

Hereinafter, the optional components that can be contained in the composition will be described in detail.

### (Basic Compound)

The composition may contain a basic compound.

The basic compound is a compound exhibiting alkalinity (pH is more than 7.0) in an aqueous solution.

Examples of the basic compound include an organic base, an inorganic base, and a salt thereof.

It is note that the basic compound does not include the quaternary ammonium salt, the solvent, or the nitrogen-containing resin.

Examples of the organic base include an amine compound, an alkanolamine compound and a salt thereof, an amine oxide compound, a nitro compound, a nitroso compound, an oxime compound, a ketoxime compound, an aldoxime compound, a lactam compound, and an isocyanide compound. The amine compound is intended to mean a compound that has an amino group in the molecule a compound, and that is not included in the alkanolamine, the amine oxide compound, and the lactam compound.

It is noted that the organic base does not include the quaternary ammonium salt or the resin containing a nitrogen atom.

Examples of the amine compound include a primary amine having a primary amino group (—NH₂) in the molecule, a secondary amine having a secondary amino group (>NH) in the molecule, and a tertiary amine having a tertiary amino group (>N—) in the molecule. Examples of the primary amine, the secondary amine, and the tertiary amine include an alkylamine, a dialkylamine, and a trialkylamine, respectively. The alkyl group may have a sub stituent.

Examples of the amine compound also include an alicyclic amine compound having an alicyclic (non-aromatic ring) structure having a nitrogen atom in the molecule, and a salt thereof. The alicyclic ring in the alicyclic amine compound may be monocyclic or polycyclic. In addition, the alicyclic ring may contain a heteroatom (for example, a nitrogen atom, an oxygen atom, or a sulfur atom). In addition, the alicyclic ring may have a substituent, and the substituent which may be included in the alicyclic ring is not particularly limited. Examples of the substituent include an alkyl group, an arylalkyl group, a hydroxyalkyl group, and an aminoalkyl group.

Examples of the salt of the amine compound include salts with the acids exemplified as the acid that forms a salt with the divalent linking group represented by Formula (X1), and among these, a hydrochloride, a sulfate, or a nitrate is preferable.

In addition, it is preferable that the amine compound is water-soluble, and the amine compound is dissolved in 1 L of water in an amount of 50 g or more.

Examples of the primary amine include methylamine, ethylamine, propylamine, butylamine, pentylamine, methoxyethylamine, methoxypropylamine, and tetrahydrofurfuryl amine.

Examples of the secondary amine include dimethylamine, diethylamine, dipropylamine, and dibutylamine (DBA).

Examples of the tertiary amine include trimethylamine, triethylamine, tripropylamine, tributylamine, ethyldimethylamine, dimethylpropylamine, diethylmethylamine, dimethylhydroxyethylamine, N-methyldiethanolamine, and benzyldimethylamine.

Examples of the alicyclic amine compound include 1,8-diazabicyclo[5.4.0]-7-undecene (DBU), 1,4-diazabicyclo[2.2.2]octane (DABCO), N-(2-aminoethyl)piperazine, hydroxyethylpiperazine, piperazine, 2-methylpiperazine, trans-2,5-dimethylpiperazine, cis-2,6-dimethylpiperazine, 2-piperidinemethanol, cyclohexylamine, and 1,5-diazabicyclo[4,3,0]-5-nonene.

Examples of the lactam compound include c-caprolactam.

Examples of the inorganic base include alkali metal hydroxides such as sodium hydroxide and potassium hydroxide, alkaline earth metal hydroxides, and ammonia or a salt thereof.

The content of the basic compound is not particularly limited, but is preferably 0.1 mass % or more and more preferably 0.5 mass % or more with respect to the total mass of the composition. The upper limit is not particularly limited, but is preferably 20.0 mass % or less with respect to the total mass of the composition.

It is also preferable that the basic compound is adjusted such that the pH of the composition, which will be described later, is in a suitable range within the above suitable range.

### (Acidic Compound)

The composition may contain an acidic compound.

The acidic compound is an acidic compound exhibiting acidity (pH is less than 7.0) in an aqueous solution.

It is noted that the acidic compound does not include the periodic acid or a salt thereof, or the resin containing a nitrogen atom.

Examples of the acidic compound include an inorganic acid, an organic acid, and a salt thereof.

Examples of the inorganic acid include sulfuric acid, hydrochloric acid, phosphoric acid, nitric acid, hydrofluoric acid, iodic acid, perchloric acid, hypochlorous acid, and a salt thereof. Among these, sulfuric acid, hydrochloric acid, phosphoric acid, nitric acid, or iodic acid is preferable, and nitric acid, sulfuric acid, hydrochloric acid, or iodic acid is more preferable.

Examples of the organic acid include a carboxylic acid, a sulfonic acid, and a salt thereof.

Examples of the carboxylic acid include formic acid, acetic acid, propionic acid, and a lower (1 to 4 carbon atoms) aliphatic monocarboxylic acid such as butyric acid, and a salt thereof.

Examples of the sulfonic acid include methanesulfonic acid, benzenesulfonic acid, p-toluenesulfonic acid (tosic acid), and a salt thereof.

As the acidic compound, sulfuric acid, hydrochloric acid, phosphoric acid, nitric acid, sulfonic acid, or a salt thereof is preferable, and sulfuric acid, hydrochloric acid, phosphoric acid, methanesulfonic acid, or p-toluenesulfonic acid is more preferable.

The content of the acidic compound is not particularly limited, but is preferably 0.1 mass % or more and more preferably 0.5 mass % or more with respect to the total mass of the composition. The upper limit is not particularly limited, but is preferably 20.0 mass % or less with respect to the total mass of the composition.

It is also preferable that the acidic compound is adjusted such that the pH of the composition, which will be described later, is in a suitable range within the above suitable range.

### (Water-Soluble Polymer)

The composition according to an embodiment of the present invention may contain a water-soluble polymer. It is noted that the water-soluble polymer does not include the nitrogen-containing resin or a compound contained in a metal corrosion inhibitor described later.

Examples of the water-soluble polymer include polyacrylic acid, polyvinyl alcohol, polyethylene glycol, polyethylene oxide, and carboxyvinyl polymer.

### (Surfactant)

The composition according to an embodiment of the present invention may contain a surfactant. It is noted that the surfactant does not include the nitrogen-containing resin.

The surfactant is not particularly limited as long as it is a compound having a hydrophilic group and a hydrophobic group (lipophilic group) in one molecule. Examples of the surfactant include an anionic surfactant and a nonionic surfactant.

The hydrophobic group included in the surfactant is not particularly limited, and examples thereof include an aliphatic hydrocarbon group, an aromatic hydrocarbon group, and a combination thereof.

In a case where the hydrophobic group includes an aromatic hydrocarbon group, the number of carbon atoms of the hydrophobic group is preferably 6 or more and more preferably 10 or more.

In a case where the hydrophobic group is composed of only an aliphatic hydrocarbon group without including an aromatic hydrocarbon group, the number of carbon atoms of the hydrophobic group is preferably 8 or more and more preferably 10 or more. The upper limit of the number of carbon atoms of the hydrophobic group is not particularly limited, but is preferably 24 or less and more preferably 20 or less.

Examples of the anionic surfactant include anionic surfactants having at least one hydrophilic group selected from the group consisting of a sulfonic acid group, a carboxy group, a sulfate ester group, and a phosphonic acid group in the molecule.

Examples of the anionic surfactant having a sulfonic acid group include alkylsulfonic acid, alkylbenzene sulfonic acid, alkylnaphthalenesulfonic acid, alkyl diphenyl ether sulfonic acid, fatty acid amidosulfonic acid, polyoxyethylene aryl ether sulfonic acid, polyoxyethylene alkyl ether sulfonic acid, polycyclic phenyl ether sulfate, and a salt thereof.

Examples of the anionic surfactant having a phosphonic acid group include polyoxypropylene alkyl ether phosphonic acid, polyoxyethylene alkyl ether phosphonic acid, and a salt thereof.

Examples of the anionic surfactant having a carboxy group include polyoxyethylene alkyl ether carboxylic acid, polyoxyethylene alkyl ether acetic acid, polyoxyethylene alkyl ether propionic acid, fatty acid, and a salt thereof.

Examples of the salt of the anionic surfactant include an ammonium salt, a sodium salt, a potassium salt, and a tetramethylammonium salt.

The surfactant may be used singly or in combination of two or more types thereof.

The content of the surfactant is preferably 0.01 mass % or more and more preferably 0.03 mass % or more with respect to the total mass of the composition. The upper limit is not particularly limited, but is preferably 10 mass % or less and more preferably 5 mass % or less with respect to the total mass of the composition from the viewpoint of suppressing foaming of the composition.

### (Insoluble Particles)

It is preferable that the composition according to an embodiment of the present invention does not substantially contain insoluble particles.

The “insoluble particles” are particles of an inorganic solid matter, an organic solid matter, and the like, and correspond to particles that are finally present as particles without being dissolved in the composition.

The expression “not substantially containing insoluble particles” indicates that the composition is diluted 10,000 times with the solvent contained in the composition to obtain a measurement composition, and the number of particles having a particle size of 50 nm or more contained in 1 mL of the measurement composition is 40,000 or less. The number of particles contained in the measurement composition can be measured in a liquid phase using a commercially available particle counter.

As a commercially available particle counter, devices manufactured by RION Co., Ltd. and devices manufactured by Particle Measuring Systems can be used. A representative example of the former device is KS-19F, and a representative example of the latter device is Chem20. In order to measure larger particles, devices such as KS-42 series and LiQuilaz II S series can be used.

Examples of the insoluble particles include particles of inorganic solid matters such as silica (including colloidal silica and fumed silica), alumina, zirconia, ceria, titania, germania, manganese oxide, and silicon carbide; and organic solid matters such as polystyrene, polyacrylic resin, and polyvinyl chloride.

Examples of the method for removing the insoluble particles from the composition include a purification treatment such as filtering.

### (Metal Corrosion Inhibitor)

The composition may contain a metal corrosion inhibitor.

It is noted that the metal corrosion inhibitor does not include the nitrogen-containing resin.

The type of the metal corrosion inhibitor is not particularly limited, and known metal corrosion inhibitors can be used.

As the metal corrosion inhibitor, a metal corrosion inhibitor containing a nitrogen atom is preferable. As the metal corrosion inhibitor, a chelating agent which will be described in detail later is exemplified.

### —Chelating Agent—

The chelating agent has at least two nitrogen-containing groups.

Examples of the nitrogen-containing group include a primary amino group, a secondary amino group, an imidazolyl group, a triazolyl group, a benzotriazolyl group, a piperazinyl group, a pyrrolyl group, a pyrrolidinyl group, a pyrazolyl group, a piperidinyl group, a guanidinyl group, a biguanidinyl group, a carbazatyl group, a hydrazidyl group, a semicarbazidyl group, and an aminoguanidinyl group.

The chelating agent may have two or more nitrogen-containing groups, and the two or more nitrogen-containing groups may be different from each other, may be partially the same, or may be all the same.

The chelating agent may also contain a carboxy group.

The nitrogen-containing group and/or the carboxy group included in the chelating agent may be neutralized to form a salt.

As the chelating agent, the chelating agents described in paragraphs [0021] to [0047] of JP2017-504190A, the contents of which are incorporated in the present specification by reference, can be used.

The chelating agent may be used singly or in combination of two or more types thereof. The content of the chelating agent is preferably 0.01 to 2 mass %, more preferably 0.1 to 1.5 mass %, and still more preferably 0.3 to 1.0 mass % with respect to the total mass of the composition.

—Other Metal Corrosion Inhibitors—

The metal corrosion inhibitor may be benzotriazole which may have a substituent. Here, the metal corrosion inhibitor does not include benzotriazole contained in the chelating agent.

Examples of the benzotriazole which may have a substituent include benzotriazole (BTA), 5-aminotetrazole, 1-hydroxybenzotriazole, 5-phenylthiol-benzotriazole, 5-chlorobenzotriazole, 4-chlorobenzotriazole, 5-bromobenzotriazole, 4-bromobenzotriazole, 5-fluorobenzotriazole, 4-fluorobenzotriazole, naphthotriazole, tolyltriazole, 5-phenyl-benzotriazole, 5-nitrobenzotriazole, 4-nitrobenzotriazole, 3-amino-5-mercapto-1,2,4-triazole, 2-(5-amino-pentyl)-benzotriazole, 1-amino-benzotriazole, 5-methyl-1H-benzotriazole, benzotriazole-5-carboxylic acid, 4-methylbenzotriazole, 4-ethylbenzotriazole, 5-ethylbenzotriazole, 4-propylbenzotriazole, 5-propylbenzotriazole, 4-isopropylbenzotriazole, 5-isopropylbenzotriazole, 4-n-butylbenzotriazole, 5-n-butylbenzotriazole, 4-isobutylbenzotriazole, 5-isobutylbenzotriazole, 4-pentylbenzotriazole, 5-pentylbenzotriazole, 4-hexylbenzotriazole, 5-hexylbenzotriazole, 5-methoxybenzotriazole, 5-hydroxybenzotriazole, dihydroxypropylbenzotriazole, 1-[N,N-bi s(2-ethylhexyl)aminomethyl]-benzotriazole, 5-t-butylbenzotriazole, 5-(1′,1′-dimethylpropyl)-benzotriazole, 5-(1′,1′,3′-trimethylbutyl)benzotriazole, 5-n-octylbenzotriazole, and 5-(1′,1′,3′,3′-tetramethylbutyl)benzotriazole.

The content of the metal corrosion inhibitor is not particularly limited, but is preferably 0.1 mass % or more and more preferably 1 mass % or more with respect to the total mass of the composition. The upper limit is not particularly limited, but is preferably 10 mass % or less, and more preferably 5 mass % or less with respect to the total mass of the composition.

### (Metal Component)

The composition may contain a metal component.

Examples of the metal component include metal particles and metal ions. For example, the content of the metal component refers to the total content of metal particles and metal ions. The composition may contain any one of metal particles or metal ions, or may contain both of them.

Examples of the metal atom contained in the metal component include a metal atom selected from the group consisting of Ag, A1, As, Au, Ba, Ca, Cd, Co, Cr, Cu, Fe, Ga, Ge, K, Li, Mg, Mn, Mo, Na, Ni, Pb, Sn, Sr, Ti, Zn, and Zr.

The metal component may contain one type of metal atom or two or more types of metal atoms.

The metal particles may be a simple substance or an alloy, and the metal may be present in a form of being associated with an organic substance.

The metal component may be a metal component unavoidably contained in each component (raw material) contained in the composition, may be a metal component unavoidably incorporated in the composition during the production, storage, and/or transfer of the composition, or may be intentionally added to the composition.

In a case where the composition contains a metal component, the content of the metal component is 0.01 ppt by mass to 10 ppm by mass in many cases, preferably 0.1 ppt by mass to 1 ppm by mass, and more preferably 0.1 ppt by mass to 100 ppb by mass with respect to the total mass of the composition.

The type and content of the metal component in the composition can be measured by single nano particle inductively coupled plasma mass spectrometry (ICP-MS).

In the ICP-MS, the content of the metal component to be measured is measured regardless of the form of the metal component. Therefore, the total mass of the metal particles and the metal ions to be measured is determined as the content of the metal component.

For the measurement by the ICP-MS, for example, Agilent 8800 triple quadrupole inductively coupled plasma mass spectrometry (ICP-MS, for semiconductor analysis, option #200) and Agilent 8900 manufactured by Agilent Technologies, and NexION350S manufactured by PerkinElmer, Inc. can be used.

A method for adjusting the content of each metal component in the composition is not particularly limited. For example, the content of the metal component in the composition can be reduced by performing a known treatment of removing metal from the composition and/or raw materials containing respective components used for preparing the composition. In addition, the content of the metal component in the composition can be increased by adding a compound containing a metal ion to the composition.

### <Properties of Composition>

Hereinafter, the chemical properties and physical properties exhibited by the composition will be described.

[pH] The pH of the composition according to an embodiment of the present invention is not particularly limited, and is, for example, in a range of 1.0 to 14.0.

Particularly, the pH of the composition is preferably 1.0 to 12.0, more preferably 3.0 to 10.0, and still more preferably 4.0 to 7.5 from the viewpoint that the Ru/W selectivity is more excellent.

In the present specification, the pH of the composition is a value obtained by measurement at 25° C. using a pH meter (F-51 (trade name) manufactured by Horiba, Ltd.).

### [Coarse Particles]

It is preferable that the composition does not substantially contain coarse particles.

The “coarse particles” mean particles having a diameter of 0.2 μm or more when the shape of the particles is regarded as a sphere. The coarse particles may include particles contained in the insoluble particles. Further, the expression “not substantially containing coarse particles” indicates that when the composition is measured using a commercially available measuring device in a light scattering type in-liquid particle measurement system, the number of particles having a diameter of 0.2 μm or more in 1 mL of the composition is 10 or less. The lower limit is preferably 0 or more.

The coarse particles contained in the composition are particles such as dust, dirt, organic solid matters, and inorganic solid matters contained as impurities in the raw material, particles such as dust, dirt, organic solid matters, and inorganic solid matters brought in as contaminants during the preparation of the composition, and the like, and those finally present as particles without being dissolved in the composition correspond to the coarse particles.

Examples of a method for measuring the content of the coarse particles include a method of performing measurement in a liquid phase using a commercially available measuring device in a light scattering type in-liquid particle measurement system using a laser as a light source.

Examples of a method for removing coarse particles include a filtering treatment.

### <Method for Producing Composition>

A method for producing the composition according to an embodiment of the present invention is not particularly limited, and the composition can be produced by, for example, mixing the respective components described above. The order or timing of mixing the respective components, and the order and timing are not particularly limited. Examples of the method include a method in which periodic acid or a salt thereof, a quaternary ammonium salt, a resin containing a nitrogen atom, and optional components are sequentially introduced in a stirrer such as a mixer containing purified pure water, and then sufficiently stirred to mix the respective components, thereby producing a composition.

Examples of the method for producing the composition also include a method in which the pH of the washing solution is adjusted in advance using the basic compound or the acidic compound, and then the respective components are mixed, and a method in which the respective components are mixed, and then the pH is adjusted to a set value using the basic compound or the acidic compound.

In addition, the composition according to an embodiment of the present invention may be produced by producing a concentrate solution having a smaller content of a solvent such as water than the content at the time of use, and diluting the concentrate solution with a diluent (preferably water) at the time of use to adjust the content of each component to a predetermined content. After diluting the concentrate solution with the diluent, the composition according to an embodiment of the present invention may be produced by adjusting the pH thereof to a set value using the basic compound or the acidic compound. When the concentrate solution is diluted, a predetermined amount of the diluent may be added to the concentrate solution, or a predetermined amount of the concentrate solution may be added to the diluent.

### [Metal Removal Step]

In the production method, a metal removal step of removing metal components from the components and/or the composition (hereinafter, also referred to as an “object to be purified”) may be performed. For example, an aspect in which the metal removal step is performed on an object to be purified containing periodic acid or a salt thereof and water is exemplified.

In the object to be purified containing periodic acid or a salt thereof and water, the content of the periodic acid or a salt thereof is not particularly limited, but is preferably 0.0001 to 50 mass %, more preferably 1 to 45 mass %, and still more preferably 4 to 40 mass % with respect to the total mass of the object to be purified. The content of water in the object to be purified is preferably 40 mass % or more and less than 100 mass %, preferably 50 to 99 mass %, and more preferably 60 to 95 mass % from the viewpoint of excellent treatment efficiency.

The object to be purified containing periodic acid or a salt thereof and water may further contain components contained in the composition and/or optional components.

Examples of the metal removal step include step P of subjecting the object to be purified to an ion exchange method.

### (Step P)

In step P, the above-described object to be purified is subjected to an ion exchange method.

The ion exchange method is not particularly limited as long as the amount of metal components in the object to be purified can be adjusted (reduced), but the ion exchange method preferably includes one or more of the following methods P1 to P3 from the viewpoint of more easily producing a chemical liquid. The ion exchange method preferably includes two or more types of methods among methods P1 to P3, and more preferably includes all of methods P1 to P3. In a case where the ion exchange method includes all of methods P1 to P3, the methods may be performed in any order without particular limitation, but are preferably performed in the order of methods P1 to P3.

Method P1: A method of passing an object to be purified through a first filled portion filled with a mixed resin containing two or more types of resins selected from the group consisting of a cation exchange resin, an anion exchange resin, and a chelate resin.

Method P2: A method of passing an object to be purified through at least one type of a second filled portion filled with a cation exchange resin, a third filled portion filled with an anion exchange resin, or a fourth filled portion filled with a chelate resin.

Method P3: A method of passing an object to be purified through a membranous ion exchanger.

The procedures of methods P1 to P3 will be described in detail below, and in a case where the ion exchange resins (cation exchange resin and anion exchange resin), the chelate resin, and the membranous ion exchanger used in the respective methods are in a form other than the H⁺ form or the OH⁻ form, the ion exchange resins, the chelate resin, and the membranous ion exchanger are preferably used after being regenerated to the H⁺ form or the OH⁻ form, respectively.

In addition, the space velocity (SV) of the object to be purified in each method is preferably 0.01 to 20.0 (1/h) and more preferably 0.1 to 10.0 (1/h).

The treatment temperature in each method is preferably 0 to 60° C. and more preferably 10 to 50° C.

In addition, examples of the form of the ion exchange resin and the chelate resin include a particle form, a fibrous form, and a porous monolithic form, and the particle form or the fibrous form is preferable.

The average particle size of the ion exchange resin and the chelate resin in the particle form is preferably 10 to 2,000 μm and more preferably 100 to 1,000 μm.

In the particle size distribution of the ion exchange resin and the chelate resin in the particle form, the abundance of resin particles having an average particle size in a range of ±200 μm is preferably 90% or more.

The average particle size and the particle size distribution may be measured, for example, using a particle size distribution analyzer (Microtrac HRA3920, manufactured by Nikkiso Co., Ltd.) and using water as a dispersion medium.

### —Method P1—

Method P1 is a method of passing an object to be purified through a first filled portion filled with a mixed resin containing two or more types of resins selected from the group consisting of a cation exchange resin, an anion exchange resin, and a chelate resin.

As the chelate resin, a known chelate resin can be used, and specifically, a chelate resin described later can be used.

As the cation exchange resin, a known cation exchange resin can be used. The cation exchange resin may be a gel-type or a macroreticular type (MR type) and among these, a gel-type cation exchange resin is preferable.

Specific examples of the cation exchange resin include a sulfonic acid type cation exchange resin and a carboxylic acid type cation exchange resin.

Examples of the cation exchange resin include Amberlite IR-124, Amberlite IR-120B, Amberlite IR-200CT, ORLITE DS-1, and ORLITE DS-4 (manufactured by Organo Corporation), DUOLITE C20J, DUOLITE C20LF, DUOLITE C255LFH, and DUOLITE C-433LF (manufactured by Sumika Chemtex Co., Ltd), C100, C150, and C100×16MBH (manufactured by Purolite International K. K.), and DIAION SK-110, DIAION SK1B, DIAION SK1BH, DIAION PK216, and DIAION PK228 (manufactured by Mitsubishi Chemical Corporation).

As the anion exchange resin, a known anion exchange resin can be used. The anion exchange resin may be a gel-type or an MR type, and among these, a gel-type anion exchange resin is preferably used.

Specific examples of the cation exchange resin include a quaternary ammonium salt type anion exchange resin.

Examples of the anion exchange resin include Amberlite IRA-400J, Amberlite IRA-410J, Amberlite IRA-900J, Amberlite IRA67, ORLITE DS-2, ORLITE DS-5, and ORLITE DS-6 (manufactured by Organo Corporation), DUOLITE A113LF, DUOLITE A 116, and DUOLITE A-375LF (manufactured by Sumika Chemtex Co., Ltd), A400 and A500 (manufactured by Purolite International K. K.), and DIAION SA12A, DIAION SA10AO, DIAION SAIOAOH, DIAION SA20A, and DIAION WA10 (manufactured by Mitsubishi Chemical Corporation).

Examples of commercially available products in which a strongly acidic cation exchange resin and a strongly alkaline anion exchange resin are mixed in advance include DUOLITE MB5113, DUOLITE UP6000, and DUOLITE UP7000 (manufactured by Sumika Chemtex Co., Ltd), Amberlite EG-4A-HG, Amberlite MB-1, Amberlite MB-2, Amberjet ESP-2, Amberjet ESP-1, ORLITE DS-3, ORLITE DS-7, and ORLITE DS-10 (manufactured by Organo Corporation), and DIAION SMNUP, DIAION SMNUPB, DIAION SMT100L, and DIAION SMT200L (all manufactured by Mitsubishi Chemical Corporation).

The mixed resin is preferably a form including a cation exchange resin and an anion exchange resin, or a form including a cation exchange resin and a chelate resin.

In a case where a mixed resin containing a cation exchange resin and an anion exchange resin is produced, the mixing ratio between both resins is preferably 1/4 to 4/1 and more preferably 1/3 to 3/1 in terms of the volume ratio of the cation exchange resin to the anion exchange resin.

Examples of a suitable combination of the cation exchange resin and the anion exchange resin include a combination of a gel-type sulfonic acid type cation exchange resin and a gel-type quaternary ammonium salt type anion exchange resin.

In a case where a mixed resin containing a cation exchange resin and a chelate resin is produced, the mixing ratio between both resins is preferably 1/4 to 4/1 and more preferably 1/3 to 3/1 in terms of the volume ratio of the cation exchange resin to the chelate resin.

Examples of a suitable combination of the cation exchange resin and the chelate resin include a combination of a gel-type sulfonic acid type cation exchange resin and a gel-type aminophosphonic acid type chelate resin.

The first filled portion includes a container, and a mixed resin containing two or more types of resins selected from the group consisting of a cation exchange resin, an anion exchange resin, and a chelate resin which are usually filled in the container.

Examples of the container include a column, a cartridge, and a packed column. The container may be a container other than those exemplified above as long as an object to be purified can pass through the container after the container is filled with the mixed resin.

In method P1, the object to be purified may be passed through at least one first filled portion. Particularly, in view of more easily producing a chemical liquid, the object to be purified may be passed through two or more first filled portions.

### —Method P2—

Method P2 is a method of passing an object to be purified through at least one type (preferably two or more types) of a second filled portion filled with a cation exchange resin, a third filled portion filled with an anion exchange resin, or a fourth filled portion filled with a chelate resin.

Examples of the cation exchange resin and the anion exchange resin that can be used in method P2 include the cation exchange resins and the anion exchange resins exemplified in the description of method P1.

The second filled portion generally includes a container and the above-described cation exchange resin filled in the container.

The third filled portion generally includes a container and the above-described anion exchange resin filled in the container.

The fourth filled portion generally includes a container and a chelate resin filled in the container, which will be described below.

The chelate resin generally refers to a resin having a coordinating group capable of forming a chelate bond with a metal ion.

The chelate resin is, for example, a resin obtained by introducing a chelate forming group into a styrene-divinylbenzene copolymer or the like. The material of the chelate resin may be a gel-type or an MR type. The chelate resin is preferably in the form of particles or fibers from the viewpoint of treatment efficiency.

Examples of the chelate resin include various chelate resins such as iminodiacetic acid type, iminopropionic acid type, aminophosphonic acid type such as aminomethylphosphonic acid type, polyamine type, glucamine type such as N-methylglucamine type, aminocarboxylic acid type, dithiocarbamic acid type, thiol type, amidoxime type, pyridine type, and phosphonic acid type chelate resins.

Specific examples of the chelate resin include: as the iminodiacetic acid type chelate resin, MC700 manufactured by Sumika Chemtex Co., Ltd, ORLITE DS-22 manufactured by Organo Corporation, and D5843 manufactured by Purolite International K. K.; as the iminopropionic acid type chelate resin, EPORAS MX-8 manufactured by Miyoshi Oil & Fat Co., Ltd.; as the aminomethylphosphonic acid type chelate resin, MC960 manufactured by Sumika Chemtex Corporation; as the aminophosphonic acid type chelate resin, ORLITE DS-21 manufactured by Organo Corporation and D5817 manufactured by Purolite International K. K.; as the polyamine type chelate resin, S985 manufactured by Purolite International K. K., DIAION CR-20 manufactured by Mitsubishi Chemical Corporation, and MC850 manufactured by Sumika Chemtex Corporation; as the N-methylglucamine type chelate resin, Amberlite IRA-743 manufactured by Organo Corporation; and as the phosphonic acid type chelate resin, S955 manufactured by Purolite International K. K.

Among these, the chelate resin is preferably an aminophosphonic acid type chelate resin from the viewpoint that a heavy metal element contained in the periodic acid can be removed.

The definition of the container in the second filled portion, the third filled portion, and the fourth filled portion is as described above.

In method P2, the object to be purified is passed through at least one type of the second filled portion, the third filled portion, or the fourth filled portion. Particularly, it is preferable that the object to be purified is passed through two or more types of filled portions among the second filled portion, the third filled portion, and the fourth filled portion.

In method P2, it is preferable that the object to be purified is passed through at least the second filled portion.

Further, when the object to be purified is passed through the fourth filled portion in method P2, even though the number of times that the object to be purified is passed through the filled portions is small, the purification can be efficiently performed.

In a case where the object to be purified is passed through two or more types of filled portions in method P2, the order of passing the object to be purified through the two or more types of filled portions among the second filled portion, the third filled portion, and the fourth filled portion may be any order.

In method P2, the object to be purified may be passed through at least one (preferably two or more) second filled portion, at least one (preferably two or more) third filled portion, and/or at least one fourth filled portion.

For example, in view of more easily producing a chemical liquid, the object to be purified may be passed through one or more (preferably two or more) second filled portions and one or more (preferably two or more) third filled portions.

In this case, the order of passing the object to be purified through the filled portions is not limited. For example, the object to be purified may be alternately passed through the second filled portion and the third filled portion, or may be continuously passed through one of the plurality of second filled portions and the third filled portion and then continuously passed through the other one of the plurality of second filled portions and third filled portions.

In addition, from the viewpoint of more easily producing a chemical liquid, the object to be purified may be passed through one or more second filled portions and one or more fourth filled portions.

Also in this case, the order of passing the object to be purified through the filled portions is not limited.

### —Method P3—

Method P3 is a method of passing an object to be purified through a membranous ion exchanger.

The membranous ion exchanger is a membrane having an ion exchange group. Examples of the ion exchange group include a cation exchange group (a sulfonic acid group or the like) and an anion exchange group (an ammonium group or the like).

The membranous ion exchanger may be made of an ion exchange resin itself, or may be produced by introducing a cation exchange group and/or an anion exchange group into a membranous support. The membranous ion exchanger (including the support of the membranous ion exchanger) may be porous or non-porous. The membranous ion exchanger (including the support of the membranous ion exchanger) may be, for example, a membrane formed from an aggregate of particles and/or fibers.

Further, for example, the membranous ion exchanger may be any of an ion exchange membrane, ion exchange nonwoven fabric, ion exchange filter paper, and ion exchange filter cloth.

The membranous ion exchanger may be used, for example, in a manner in which the membranous ion exchanger is incorporated into a cartridge as a filter and an aqueous solution is passed through the filter.

A membranous ion exchanger of semiconductor grade is preferably used.

Examples of commercially available products of the membranous ion exchanger include Mustang (manufactured by Pall Corporation) and Protego (registered trademark) Plus LT Purifier (manufactured by Entegris Inc).

The thickness of the membranous ion exchanger is not particularly limited, and is preferably, for example, 0.01 to 1 mm.

The flow rate of the aqueous solution is, for example, 1 to 100 mL/(min·cm²).

In method P3, the object to be purified may be passed through at least one membranous ion exchanger. Particularly, in view of more easily producing a chemical liquid, the object to be purified may be passed through two or more membranous ion exchangers.

In a case where two or more membranous ion exchangers are used, at least one membranous ion exchanger having a cation exchange group and at least one ion exchanger having an anion exchange group may be used.

The ion exchange method is preferably performed until the content of the metal components contained in the object to be purified falls within the above preferred range of the content of the metal components.

### [Filtration Step]

The production method preferably includes a filtration step of filtering the liquid in order to remove foreign matters, coarse particles, and the like from the liquid.

The filtering method is not particularly limited, and a known filtering method can be used. In particular, filtering using a filter is preferable.

As a filter used for filtering, any filter which has been used in the filtering application and the like can be used without particular limitation. Examples of the material constituting the filter include fluorine-based resins such as polytetrafluoroethylene (PTFE), polyamide-based resins such as nylon, polyolefin resins (including high-density and ultra-high-molecular-weight polyolefin resins) such as polyethylene and polypropylene (PP), and polyarylsulfone. Among these, a polyamide-based resin, PTFE, polypropylene (including high-density polypropylene), and polyarylsulfone are preferable.

High-polarity foreign matters which are likely to cause defects can be more effectively removed from the composition by using a filter formed of such a material.

The lower limit value of the critical surface tension of the filter is preferably 70 mN/m or more, and the upper limit value thereof is preferably 95 mN/m or less. In particular, the critical surface tension of the filter is preferably 75 to 85 mN/m.

It is noted that the value of the critical surface tension is a nominal value of the manufacturers. High-polarity foreign matters which are likely to cause defects can be more effectively removed from the composition by using a filter having a critical surface tension in the above range.

The pore diameter of the filter is preferably about 0.001 to 1.0 μm, more preferably about 0.02 to 0.5 μm, and still more preferably about 0.01 to 0.1 μm. When the pore diameter of the filter is set to be in the above range, fine foreign matters contained in the composition can be reliably removed while suppressing filter clogging.

At the time of using the filter, different filters may be used in combination. At this time, the filtering using a first filter may be performed only once or two or more times. In a case where filtering is performed two or more times by combining different filters, the filters may be of the same type or of different types, but preferably of different types. Typically, it is preferable that at least one of the pore diameter or the constituent material is different between a first filter and a second filter.

It is preferable that the pore diameter for the second and subsequent filtering is the same as or smaller than the pore diameter for the first filtering. Further, first filters having different pore diameters may be combined within the above range. The pore diameter used herein can refer to a nominal value of the filter manufacturers. A commercially available filter can be selected from various filters provided from, for example, Nihon Pall Ltd., Advantec Toyo Kaisha, Ltd., Entegris Japan Co., Ltd. (former Nihon Mykrolis KK), and Kitz Micro Filter Corporation.

In addition, “P-nylon filter (made of polyamide, pore diameter: 0.02 μm, critical surface tension: 77 mN/m)”; (manufactured by Nihon Pall Ltd.), “PE-clean filter (made of high-density polyethylene, pore diameter: 0.02 μm)”; (manufactured by Nihon Pall Ltd.), and “PE-clean filter (made of high-density polyethylene, pore diameter: 0.01 μm)”; (manufactured by Nihon Pall Ltd.) can also be used.

As the second filter, a filter formed of the same material as the first filter can be used. A filter having the same pore diameter as that of the first filter can be used. In a case of using the second filter having a smaller pore diameter than that of the first filter, the ratio of the pore diameter of the second filter to the pore diameter of the first filter (pore diameter of second filter/pore diameter of first filter) is preferably 0.01 to 0.99, more preferably 0.1 to 0.9, and still more preferably 0.3 to 0.9. When the pore diameter of the second filter is set to be in the above range, fine foreign matters mixed into the composition are more reliably removed.

For example, the filtering using the first filter is performed using a mixed solution containing some components of the composition, and after the remaining components are mixed with the filtrate to prepare a composition, the second filtering may be performed.

It is preferable that the filter to be used is subjected to a treatment before filtering the composition. The liquid used for this treatment is not particularly limited, but is preferably a liquid containing the composition and components contained in the composition.

When filtering is performed, the upper limit value of the temperature during filtering is preferably room temperature (25° C.) or lower, more preferably 23° C. or lower, and still more preferably 20° C. or lower. Further, the lower limit value of the temperature during filtering is preferably 0° C. or higher, more preferably 5° C. or higher, and still more preferably 10° C. or higher.

Particulate foreign matters and/or impurities can be removed by filtering, but when filtering is performed at the above-described temperature, the amount of particulate foreign matters and/or impurities dissolved in the composition is reduced, and thus filtering is more efficiently performed.

### [Charge Elimination Step]

The method for producing a composition may further include a charge elimination step of subjecting the composition to charge elimination.

### [Container]

As the container for storing the composition, for example, a known container can be used.

As the container, a container used for semiconductor applications, which has high cleanliness in the container and causes less elution of impurities, is preferable.

Examples of the container include “Clean Bottle” series (manufactured by Aicello Corporation) and “Pure Bottle” (manufactured by Kodama Plastics Co., Ltd.). In addition, from the viewpoint of preventing impurities from being mixed (contamination) into the raw materials and the composition, it is also preferable to use a multilayer container that has an inner wall having a six layer structure including six types of resins or a multilayer container that has an inner wall having a seven layer structure including seven types of resins.

Examples of the multilayer container include the container described in JP2015-123351A, the contents of which are incorporated herein by reference.

Examples of the material of the inner wall of the container include a first resin which is at least one selected from the group consisting of polyethylene resin, polypropylene resin, polyethylene-polypropylene resin, a second resin different from the first resin, and metals such as stainless steel, Hastelloy, Inconel, and Monel. In addition, it is preferable that the inner wall of the container is formed of or coated with the above-described materials.

As the second resin, a fluororesin (perfluoro resin) is preferable.

In a case where a fluororesin is used, the elution of ethylene or propylene oligomers can be suppressed.

Examples of the container include a FluoroPurePFA composite drum (manufactured by Entegris Inc), and the containers described in page 4 of JP1991-502677A (JP-H11-502677A), page 3 of WO2004/016526A, and pages 9 and 16 of WO99/046309A.

As the inner wall of the container, in addition to fluororesin, for example, quartz and an electropolished metal material (metal material which has been electropolished) are also preferable.

The metal material used for the electropolished metal material contains at least one selected from the group consisting of chromium (Cr) and nickel (Ni). The total content of Cr and Ni is preferably more than 25 mass % with respect to the total mass of the metal material. Examples of the metal material include stainless steel and a Ni—Cr alloy.

The total content of Cr and Ni in the metal material is preferably 25 mass % or more and more preferably 30 mass % or more with respect to the total mass of the metal material. The upper limit is preferably 90 mass % or less with respect to the total mass of the metal material.

Examples of the stainless steel include known stainless steel.

In particular, stainless steel containing 8 mass % or more of Ni is preferable, and austenitic stainless steel containing 8 mass % or more of Ni is more preferable.

Examples of the austenitic stainless steel include steel use stainless (SUS) 304 (Ni content: 8 mass %, Cr content: 18 mass %), SUS304L (Ni content: 9 mass %, Cr content: 18 mass %), SUS316 (Ni content: 10 mass %, Cr content: 16 mass %), and SUS316L (Ni content: 12 mass %, Cr content: 16 mass %).

Examples of the Ni—Cr alloy include known Ni—Cr alloys.

Among these, a Ni—Cr alloy having a Ni content of 40 to 75 mass % and a Cr content of 1 to 30 mass % is preferable.

Examples of the Ni—Cr alloy include Hastelloy, Monel, and Inconel. Specific examples of the Ni—Cr alloy include Hastelloy C-276 (Ni content: 63 mass %, Cr content: 16 mass %), Hastelloy-C(Ni content: 60 mass %, Cr content: 17 mass %), and Hastelloy C-22 (Ni content: 61 mass %, Cr content: 22 mass %).

The Ni—Cr alloy may further contain boron, silicon, tungsten, molybdenum, copper, or cobalt as necessary, in addition to the above-described alloys.

Examples of the method for electropolishing the metal material include known methods.

Specific examples of the method include the methods described in paragraphs [0011] to [0014] of JP2015-227501A and paragraphs [0036] to [0042] of JP2008-264929A, the contents of which are incorporated herein by reference.

It is preferable that the metal material is buffed.

Examples of the buffing method include known methods.

The size of the abrasive grains used for finishing the buffing is preferably #400 or less from the viewpoint that the unevenness of the surface of the metal material is easily reduced. Incidentally, buffing is preferably performed before the electropolishing.

In addition, the metal material may be subjected to a treatment including one or a combination of two or more of buffing, pickling, magnetic fluid polishing, and the like, and the buffing is performed in a plurality of stages by changing the order of the size or the like of abrasive grains.

The inside of the container is preferably washed before the container is filled with the composition.

The liquid used for washing can be appropriately selected according to the application, and is preferably a liquid containing at least one of the composition or the components added to the composition.

From the viewpoint of preventing a change of the components in the composition during storage, the inside of the container may be substituted with an inert gas (for example, nitrogen and argon) having a purity of 99.99995 vol % or more. In particular, a gas having a low moisture content is preferable. In addition, during transportation and storage of the container storing the composition, the temperature may be room temperature or controlled temperature. Above all, it is preferable to control the temperature in the range of −20 to 20° C. from the viewpoint of preventing deterioration.

### <Method for Treating Object to be Treated>

Hereinafter, a method for treating an object to be treated containing Ru and W (object to be treated) using the composition according to an embodiment of the present invention will be described. First, the object to be treated will be described.

### <Object to be Treated>

The object to be treated contains Ru and W.

Ru and W in the object to be treated are preferably present on the substrate. Further, Ru in the object to be treated may be a Ru-containing substance which contains Ru and another element. In addition, W in the object to be treated may be a W-containing substance which contains Wand another element. That is, it is preferable that the object to be treated is a substrate in which a Ru-containing substance and a W-containing substance are present.

Here, the composition according to an embodiment of the present invention is preferably used for selectively removing the Ru-containing substance with respect to the W-containing substance on the substrate.

In the present specification, the expression “on the substrate” includes, for example, any of the front and back, the side surface, and the inside of the groove of the substrate, and the like. The Ru-containing substance on the substrate includes not only a case where the Ru-containing substance is present directly on the surface of the substrate, but also a case where the Ru-containing substance is present on the substrate via another layer.

Hereinafter, a recess portion provided in the substrate, such as a groove and a hole is also referred to as a “groove and the like”.

In addition, the fact that a Ru-containing substance and a W-containing substance are present in the object to be treated refers to a state in which the Ru-containing substance and the W-containing substance can come into contact with the composition when the object to be treated is brought into contact with the composition. In addition, the state in which the Ru-containing substance and the W-containing substance can come into contact with the composition includes not only an aspect in which the Ru-containing substance and the W-containing substance are exposed to the outside, but also an aspect in which a member covering the Ru-containing substance or the W-containing substance is removed by some action and the Ru-containing substance or the W-containing substance can be exposed.

The type of the substrate is not particularly limited, but a semiconductor substrate is preferable.

Examples of the substrate include a semiconductor wafer, a glass substrate for a photomask, a glass substrate for a liquid crystal display, a glass substrate for a plasma display, a substrate for a field emission display (FED), a substrate for an optical disk, a substrate for a magnetic disk, and a substrate for a magneto-optical disk.

Examples of the material constituting the semiconductor substrate include silicon, germanium, silicon germanium, Group III-V compounds such as GaAs, and a combination thereof.

The use of the object to be treated which has been treated with the composition according to an embodiment of the present invention is not particularly limited. For example, the object to be treated may be used for a dynamic random access memory (DRAM), a ferroelectric random access memory (FRAM (registered trademark)), a magnetoresistive random access memory (MRAM), a phase change random access memory (PRAM), or may be used for a logic circuit, a processor, and the like.

The Ru-containing substance is not particularly limited as long as it is a substance containing Ru (Ru atom), and examples thereof include a simple substance of Ru, an alloy containing Ru, a Ru oxide, a Ru nitride, and a Ru oxynitride.

The Ru oxide, the Ru nitride, and the Ru oxynitride may be a composite oxide, a composite nitride, and a composite oxynitride containing Ru.

The content of Ru atoms in the Ru-containing substance is preferably 10 mass % or more, more preferably 30 mass % or more, still more preferably 50 mass % or more, and particularly preferably 90 mass % or more with respect to the total mass of the Ru-containing substance. The upper limit is not particularly limited, but is preferably 100 mass % or less with respect to the total mass of the Ru-containing substance.

The Ru-containing substance may contain another transition metal.

Examples of the transition metal include rhodium (Rh), titanium (Ti), tantalum (Ta), cobalt (Co), chromium (Cr), hafnium (Hf), osmium (Os), platinum (Pt), nickel (Ni), manganese (Mn), copper (Cu), zirconium (Zr), molybdenum (Mo), lanthanum (La), and iridium (Ir).

The form of the Ru-containing substance on the substrate is not particularly limited, and may be, for example, any of forms in which the Ru-containing substance is arranged in a film form, a wiring form, a plate form, a columnar form, or a particle form.

Examples of the form in which the Ru-containing substance is arranged in the particle form include: as will be described later, a substrate in which after dry-etching a substrate on which a Ru-containing film is disposed, a particulate Ru-containing substance as a residue adheres to the substrate; a substrate in which after performing chemical mechanical polishing (CMP) on a Ru-containing film, a particulate Ru-containing substance as a residue adheres to the substrate; and a substrate in which after depositing a Ru-containing film on a substrate, a particulate Ru-containing substance adheres to a region other than a Ru-containing film formation region (region where the Ru-containing film is to be formed).

The thickness of the Ru-containing film is not particularly limited and may be appropriately selected according to the use. For example, the thickness is preferably 200 nm or less, more preferably 100 nm or less, and still more preferably 50 nm or less. The lower limit is not particularly limited, but is preferably 0.1 nm or more.

The Ru-containing film may be disposed on only one main surface of the substrate, or may be disposed on both main surfaces of the substrate. Further, the Ru-containing film may be disposed on the entire main surface of the substrate, or may be disposed on a part of the main surface of the substrate.

The W-containing substance is not particularly limited as long as it is a substance containing W (W atom), and examples thereof include a simple substance of W, an alloy containing W, a W oxide, a W nitride, a W oxynitride, a W carbide, and a W boride.

The W oxide, the W nitride, the W oxynitride, and the W carbide may be a composite oxide, a composite nitride, a composite oxynitride, and a composite carbide containing W.

The content of W atoms in the W-containing substance is preferably 10 mass % or more, more preferably 30 mass % or more, still more preferably 50 mass % or more, and particularly preferably 90 mass % or more with respect to the total mass of the W-containing substance. The upper limit is not particularly limited, but is preferably 100 mass % or less with respect to the total mass of the W-containing substance.

The W-containing substance may contain another transition metal.

Examples of the transition metal include rhodium (Rh), titanium (Ti), tantalum (Ta), cobalt (Co), chromium (Cr), hafnium (Hf), osmium (Os), platinum (Pt), nickel (Ni), manganese (Mn), copper (Cu), zirconium (Zr), molybdenum (Mo), lanthanum (La), and iridium (Ir).

The form of the W-containing substance on the substrate is not particularly limited, and may be, for example, any of forms in which the W-containing substance is arranged in a film form, a wiring form, a plate form, a columnar form, or a particle form.

The thickness of the W-containing film is not particularly limited and may be appropriately selected according to the use. For example, the thickness is preferably 200 nm or less, more preferably 100 nm or less, and still more preferably 50 nm or less. The lower limit is not particularly limited, but is preferably 0.1 nm or more.

The W-containing film may be disposed on only one main surface of the substrate, or may be disposed on both main surfaces of the substrate. Further, the W-containing film may be disposed on the entire main surface of the substrate, or may be disposed on a part of the main surface of the substrate.

The object to be treated may also include various layers or structures as desired, in addition to the Ru-containing substance and the W-containing substance. For example, one or more members selected from the group consisting of metal wiring, a gate electrode, a source electrode, a drain electrode, an insulating film, a ferromagnetic layer, a non-magnetic layer, and the like may be disposed on the substrate.

The substrate may include an exposed integrated circuit structure. Examples of the integrated circuit structure include interconnection mechanisms such as metal wiring and a dielectric material. Examples of metals and alloys used for the interconnection mechanism include aluminum, a copper aluminum alloy, copper, titanium, tantalum, cobalt, silicon, titanium nitride, tantalum nitride, and molybdenum. The substrate may include layers of one or more materials selected from the group consisting of silicon oxide, silicon nitride, silicon carbide, and carbon-doped silicon oxide.

The size, thickness, shape, layer structure, and the like of the substrate are not particularly limited, and can be appropriately selected as desired.

### [Method for Producing Object to be Treated]

A method for producing an object to be treated is not particularly limited, and a known production method can be used.

As the method for producing an object to be treated, for example, a Ru-containing film and/or a W-containing film can be formed on a substrate by sputtering, chemical vapor deposition (CVD), molecular beam epitaxy (MBE), and atomic layer deposition (ALD).

When the Ru-containing film is formed by the above-described production method, in a case where a structure having unevenness is present on the substrate, the Ru-containing film may be formed on all surfaces of the structure.

In particular, in a case where the Ru-containing film is formed by sputtering and CVD, the Ru-containing film may also adhere to the back surface (the surface opposite to the Ru-containing film side) of the substrate on which the Ru-containing film is disposed.

In addition, Ru-containing wiring and/or W-containing wiring may be formed on the substrate by performing the above-described method through a predetermined mask.

In addition, a substrate on which the Ru-containing film, the Ru-containing wiring, the W-containing film, and/or the W-containing wiring is disposed may be subjected to a predetermined treatment, and used as an object to be treated by the treatment method according to an embodiment of the present invention.

For example, the substrate may be dry-etched to produce a substrate having a Ru-containing dry etching residue and a W-containing substance. The substrate may also be subjected to CMP to produce a substrate having a Ru-containing substance and a W-containing substance. Further, a Ru-containing film may be deposited on a Ru-containing film formation region in the substrate by sputtering, CVD, molecular beam epitaxy, or atomic layer deposition to produce a substrate having a Ru-containing substance adhering to a region other than the Ru-containing film formation region and a W-containing substance.

### <Method for Treating Object to be Treated>

Regarding a method for treating an object to be treated containing Ru and W (object to be treated) using the composition according to an embodiment of the present invention, typically, a method for treating a substrate on which a Ru-containing substance and a W-containing substance are present will be described. Hereinafter, the substrate on which a Ru-containing substance and a W-containing substance are present is also simply referred to as a “substrate to be treated”.

### [Step A]

A method for treating a substrate to be treated (hereinafter, also referred to as the “present treatment method”) includes step A of removing a Ru-containing substance on a substrate by using the composition according to an embodiment of the present invention.

The substrate on which a Ru-containing substance and a W-containing substance are disposed (substrate to be treated), which is an object to be treated by the present treatment method, is as described above.

Examples of the specific method of step A include a method of bringing a substrate to be treated, which is an object to be treated, into contact with the composition.

Examples of the method for bringing the substrate to be treated into contact with the composition is not particularly limited, and examples thereof include a method of immersing the object to be treated in the composition charged in a tank, a method of spraying the composition onto the object to be treated, a method of causing the composition to flow onto the object to be treated, and a combination thereof. Among these, a method of immersing the object to be treated in the composition is preferable.

In addition, in order to further enhance the washing ability of the composition, a mechanical stirring method may be used.

Examples of the mechanical stirring method include a method of circulating the composition on an object to be treated, a method of causing the composition to flow on the object to be treated or spraying the composition onto the object to be treated, and a method of locally stirring the composition in the vicinity of the substrate by irradiation with ultrasonic waves (for example, megasonic waves).

The treatment time of step A can be appropriately adjusted. The treatment time (contact time between the composition and the object to be treated) is not particularly limited, but is preferably 0.25 to 10 minutes and more preferably 0.5 to 2 minutes.

The temperature of the composition during the treatment is not particularly limited, but is preferably 20 to 75° C., more preferably 20 to 60° C., still more preferably 40 to 65° C., and particularly preferably 50 to 65° C.

In step A, a treatment of adding a solvent and one or more selected from the group consisting of the components of the composition to the composition as necessary while measuring the concentration of one or more components selected from the group consisting of periodic acid or a salt thereof, a quaternary ammonium salt, a resin containing a nitrogen atom, a solvent, and optional components in the composition may be performed. By performing this treatment, the concentration of the components in the composition can be stably maintained in a predetermined range. Water is preferred as the solvent.

Examples of a specific suitable aspect of step A include: step A1 of performing a recess etching treatment on Ru-containing wiring or Ru-containing liner disposed on a substrate, by using the composition; step A2 of removing a Ru-containing film at the outer edge portion of a substrate on which the Ru-containing film is disposed, by using the composition; step A3 of removing a Ru-containing substance adhering to the back surface of a substrate on which the Ru-containing film is disposed, by using the composition; step A4 of removing a Ru-containing substance on a substrate which has been dry-etched, by using the composition; step A5 of removing a Ru-containing substance on a substrate which has been subjected to chemical mechanical polishing, by using the composition; and step A6 of removing, by using the composition, a ruthenium-containing substance in a region other than a ruthenium-containing film formation region on a substrate on which a ruthenium-containing film has been deposit in the ruthenium-containing film formation region.

According to the method for treating a substrate using the composition according to an embodiment of the present invention, the W-containing substance present in the substrate to be treated is not removed in the steps.

Hereinafter, the present treatment method used in each of the treatments will be described.

### (Step A1)

Examples of step A include step A1 of performing a recess etching treatment on Ru-containing wiring (wiring containing Ru) and Ru-containing liner (liner containing Ru) disposed on a substrate, by using the composition.

Hereinafter, as examples of the object to be treated in step A1, a substrate having Ru-containing wiring and a substrate having Ru-containing liner will be specifically described.

### <Substrate Having Ru-Containing Wiring>

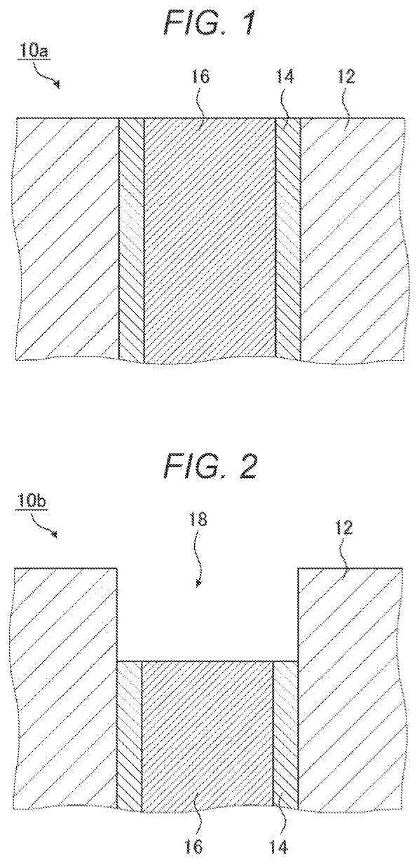

FIG. 1 is a schematic cross-sectional top view showing a substrate having Ru-containing wiring (hereinafter, also referred to as a “Ru wiring board”), which is an example of an object to be treated by the recess etching treatment in step A1.

A Ru wiring board 10a shown in FIG. 1 has a substrate (not shown), an insulating film 12 disposed on the substrate and having a groove and the like, a barrier metal layer 14 disposed along the inner wall of the groove and the like, and Ru-containing wiring 16 filled in the groove and the like.

In addition, a W-containing substance (not shown) is present in the Ru wiring board 10a.

The Ru-containing wiring in the Ru wiring board preferably contains a simple substance of Ru, an alloy of Ru, an oxide of Ru, a nitride of Ru, or an oxynitride of Ru.

The material constituting the barrier metal layer in the Ru wiring board is not particularly limited, and examples thereof include Ti metal, a Ti nitride, a Ti oxide, a Ti—Si alloy, a Ti—Si composite nitride, a Ti-A1 alloy, Ta metal, a Ta nitride, and a Ta oxide.

In FIG. 1, an aspect in which the Ru wiring board has the barrier metal layer has been described, but a Ru wiring board having no barrier metal layer may also be employed.

In step A1, a recess portion can be formed by performing a recess etching treatment on the Ru wiring board by using the composition to remove a part of the Ru-containing wiring.

More specifically, as shown in the Ru wiring board 10b in FIG. 2, when step A1 is performed, a part of the barrier metal layer 14 and the Ru-containing wiring 16 is removed, whereby a recess portion 18 is formed.

In the Ru wiring board 10b of FIG. 2, an aspect in which a part of the barrier metal layer 14 and the Ru-containing wiring 16 is removed is shown, but the recess portion 18 may also be formed by removing only a part of the Ru-containing wiring 16 without removing the barrier metal layer 14.

In the above-described treatment, the W-containing substance is not removed.

The method for producing the Ru wiring board is not particularly limited, and examples thereof include a method including a step of forming an insulating film on a substrate, a step of forming a groove and the like in the insulating film, a step of forming a barrier metal layer on the insulating film, a step of forming a Ru-containing film so as to fill the groove and the like, and a step of performing a planarization treatment on the Ru-containing film.

### <Substrate Having Ru-Containing Liner>

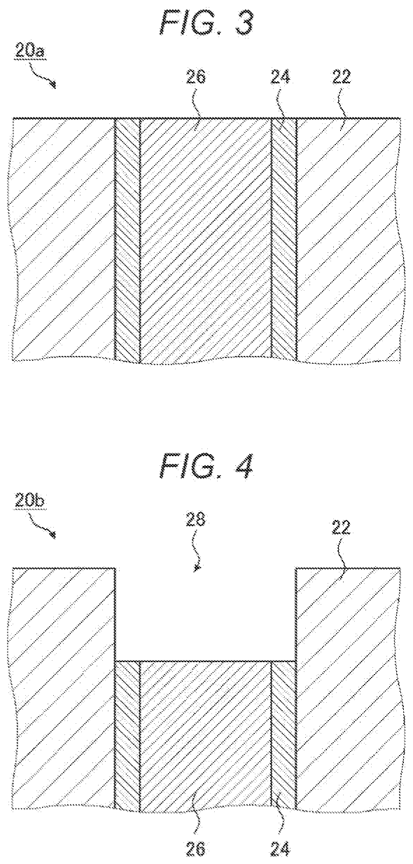

FIG. 3 is a schematic cross-sectional top view showing a substrate having Ru-containing liner (hereinafter, referred to as a “Ru liner substrate”), which is another example of an object to be treated by the recess etching treatment in step A1.

A Ru liner substrate 20a shown in FIG. 3 has a substrate (not shown), an insulating film 22 disposed on the substrate and having a groove and the like, Ru-containing liner 24 disposed along the inner wall of the groove and the like, and a wiring portion 26 filled in the groove and the like.

In addition, a W-containing substance (not shown) is present in the Ru liner substrate 20a.

The Ru-containing liner in the Ru liner substrate preferably contains a simple substance of Ru, an alloy of Ru, an oxide of Ru, a nitride of Ru, or an oxynitride of Ru.

In the Ru liner substrate shown in FIG. 3, a barrier metal layer may be separately provided between the Ru-containing liner 24 and the insulating film 22. Examples of the material constituting the barrier metal layer are the same as those in the case of the Ru wiring board.

The material constituting the wiring portion in the Ru liner substrate is not particularly limited, and examples thereof include Cu metal, W metal, Mo metal, and Co metal.

In step A1, a recess portion can be formed by performing a recess etching treatment on the Ru liner substrate by using the composition to remove a part of the Ru-containing liner.

More specifically, as shown in the Ru liner substrate 20b of FIG. 4, when step A1 is performed, a part of the Ru-containing liner 24 and the wiring portion 26 is removed, whereby a recess portion 28 is formed.

In the above-described treatment, the W-containing substance is not removed.

The method for producing the Ru liner substrate is not particularly limited, and examples thereof include a method including a step of forming an insulating film on a substrate, a step of forming a groove and the like in the insulating film, a step of forming Ru liner on the insulating film, a step of forming a metal film so as to fill the groove and the like, and a step of performing a planarization treatment on the metal film.

Examples of the specific method of step A1 include a method of bringing the Ru wiring board or the Ru liner substrate into contact with the composition.

The method of bringing the Ru wiring board or the Ru liner substrate into contact with the composition is as described above.

Suitable ranges of the contact time between the Ru wiring board or the Ru liner substrate and the composition, and the temperature of the composition are as described above.

### (Step B)

Step B of treating the substrate obtained by step A1 by using a predetermined solution (hereinafter, also referred to as a “specific solution”) may be performed as necessary before or after step A1.

In particular, in a case where a barrier metal layer is disposed on a substrate, components constituting the Ru-containing wiring or the Ru liner (hereinafter, also referred to as “Ru-containing wiring or the like”) and components constituting the barrier metal layer may have different dissolving abilities to the composition according to an embodiment of the present invention depending on the type thereof. In such a case, it is preferable to adjust the degree of dissolution between the Ru-containing wiring or the like and the barrier metal layer by using a solution having a higher dissolving ability for the barrier metal layer.

From such a viewpoint, the specific solution is preferably a solution having a poor dissolving ability for the Ru-containing wiring or the like and an excellent dissolving ability for the substance constituting the barrier metal layer.

The specific solution preferably has a low dissolving ability for the W-containing substance.

The specific solution is, for example, a solution selected from the group consisting of a mixed solution (FPM) of hydrofluoric acid and aqueous hydrogen peroxide, a mixed solution (SPM) of sulfuric acid and aqueous hydrogen peroxide, a mixed solution (APM) of aqueous ammonia and aqueous hydrogen peroxide, and a mixed solution (HPM) of hydrochloric acid and aqueous hydrogen peroxide.

The composition of the FPM is, for example, preferably in a range of “hydrofluoric acid:aqueous hydrogen peroxide:water=1:1:1” to “hydrofluoric acid:aqueous hydrogen peroxide:water=1:1:200” (volume ratio).

The composition of the SPM is preferably, for example, in a range of “sulfuric acid aqueous hydrogen peroxide:water=3:1:0” to “sulfuric acid:aqueous hydrogen peroxide water=1:1:10” (volume ratio).

The composition of the APM is preferably, for example, in a range of “aqueous ammonia:aqueous hydrogen peroxide:water=1:1:1” to “aqueous ammonia:aqueous hydrogen peroxide:water=1:1:30” (volume ratio).

The composition of the HPM is, for example, preferably in a range of “hydrochloric acid:aqueous hydrogen peroxide:water=1:1:1” to “hydrochloric acid:aqueous hydrogen peroxide:water=1:1:30” (volume ratio).

These preferred compositional ratios mean a compositional ratio determined in a case where the content of hydrofluoric acid is 49 mass %, the content of sulfuric acid is 98 mass %, the content of aqueous ammonia is 28 mass %, the content of hydrochloric acid is 37 mass %, and the content of aqueous hydrogen peroxide is 31 mass %.

Among these, the specific solution is preferably SPM, APM, or HPM from the viewpoint of the dissolving ability for the barrier metal layer.

The specific solution is preferably APM, HPM, or FPM, and more preferably APM from the viewpoint of reducing roughness.

The specific solution is preferably APM or HPM from the viewpoint of excellent balance of performance.

In step B, the method for treating the substrate obtained by step A1 by using the specific solution is preferably a method of bringing the substrate obtained by step A1 into contact with the specific solution.

The method of bringing the substrate obtained by step A1 into contact with the specific solution is not particularly limited, and examples thereof include the same method as the method for bringing the substrate into contact with the composition.

The contact time between the specific solution and the substrate obtained in step A1 is, for example, preferably 0.25 to 10 minutes and more preferably 0.5 to 5 minutes.

In the present treatment method, step A1 and step B may be alternately repeated.

In a case where the steps are alternately repeated, it is preferable that each of step A1 and step B is performed 1 to 10 times. Further, in a case where step A1 and step B are alternately repeated, the step performed firstly and the step performed lastly may be any of step A1 or step B.

### (Step A2)

Examples of step A include step A2 of removing a Ru-containing film at the outer edge portion of a substrate on which the Ru-containing film is disposed, by using the composition.

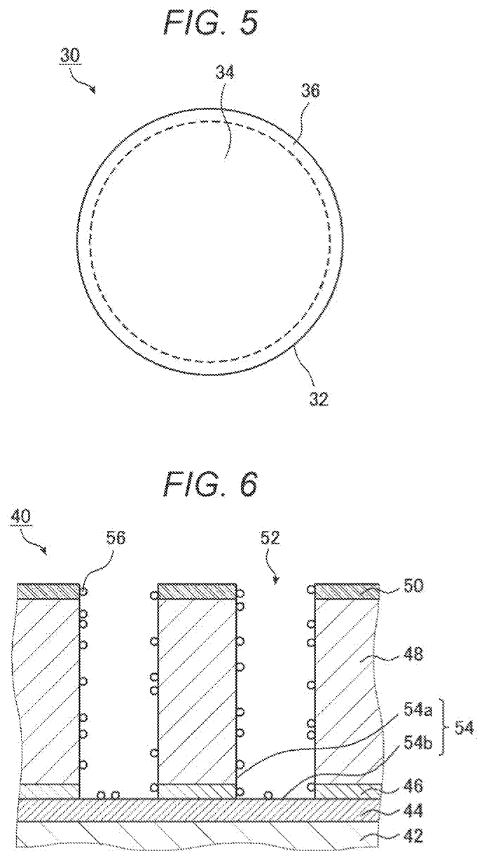

FIG. 5 is a schematic view (top view) showing an example of a substrate on which a Ru-containing film as an object to be treated in step A2 is disposed.

An object to be treated 30 in step A2, shown in FIG. 5, is a laminate having a substrate 32 and a Ru-containing film 34 disposed on one main surface (entire region surrounded by the solid line) of the substrate 32. As will be described later, in step A2, the Ru-containing film 34, which is located at an outer edge portion 36 (a region outside the broken line) of the object to be treated 30, is removed.

In addition, a W-containing substance (not shown) is present in the object to be treated 30.

The substrate and the Ru-containing film in the object to be treated are as described above.

The Ru-containing film preferably contains a simple substance of Ru, an alloy of Ru, an oxide of Ru, a nitride of Ru, or an oxynitride of Ru.

The specific method of step A2 is not particularly limited, and examples thereof include a method of supplying the composition from a nozzle such that the composition comes into contact with only the Ru-containing film at the outer edge portion of the substrate.

In the treatment of step A2, the substrate treatment devices and the substrate treatment methods described in JP 2010-267690A, JP2008-080288A, JP2006-100368A, and JP2002-299305A can be preferably applied.

The method for bringing the composition into contact with the object to be treated is as described above.

Suitable ranges of the contact time between the composition and the object to be treated, and the temperature of the composition are as described above.

The W-containing substance is not removed in step A2.

### (Step A3)

Examples of step A include step A3 of removing a Ru-containing substance adhering to the back surface of a substrate on which the Ru-containing film is disposed, by using the composition.

Examples of the object to be treated in step A3 include the object to be treated used in step A2. In the formation of the object to be treated including the substrate and the Ru-containing film disposed on one main surface of the substrate, which is used in step A2, the Ru-containing film is formed by sputtering, CVD, or the like. At this time, a Ru-containing substance may adhere to the surface (back surface) opposite to the Ru-containing film side of the substrate. Step A3 is performed to remove such a Ru-containing substance in the object to be treated.

The specific method of step A3 is not particularly limited, and examples thereof include a method of spraying the composition such that the composition comes into contact with only the back surface of the substrate.

The method for bringing the composition into contact with the object to be treated is as described above.

Suitable ranges of the contact time between the composition and the object to be treated, and the temperature of the composition are as described above.

The W-containing substance is not removed in step A3.

### (Step A4)

Examples of step A include step A4 of removing a Ru-containing substance on a substrate which has been dry-etched, by using the composition.

FIGS. 6 and 8 are schematic views showing an example of the object to be treated in step A4.

Hereinafter, the individual drawings will be described.

An object to be treated 40 shown in FIG. 6 includes a Ru-containing film 44, an etching stop layer 46, an interlayer insulating film 48, and a metal hard mask 50 in this order on a substrate 42. A groove and the like 52 are formed at predetermined positions by a dry etching step and the like, and the Ru-containing film 44 is exposed through the groove and the like 52. That is, the object to be treated 40 shown in FIG. 6 is a laminate including the substrate 42, the Ru-containing film 44, the etching stop layer 46, the interlayer insulating film 48, and the metal hard mask 50 in this order. The object to be treated has the groove and the like 52 penetrating at the position of the opening of the metal hard mask 50 from the surface of the metal hard mask 50 to the surface of the Ru-containing film 44. An inner wall 54 of the groove and the like 52 is constituted of a cross-sectional wall 54a consisting of the etching stop layer 46, the interlayer insulating film 48, and the metal hard mask 50, and a bottom wall 54b consisting of the exposed Ru-containing film 44, and adry etching residues 56 is attached to the inner wall 54 of the groove and the like.

The dry etching residue contains a Ru-containing substance.

In addition, a W-containing substance (not shown) is present in the object to be treated 40.

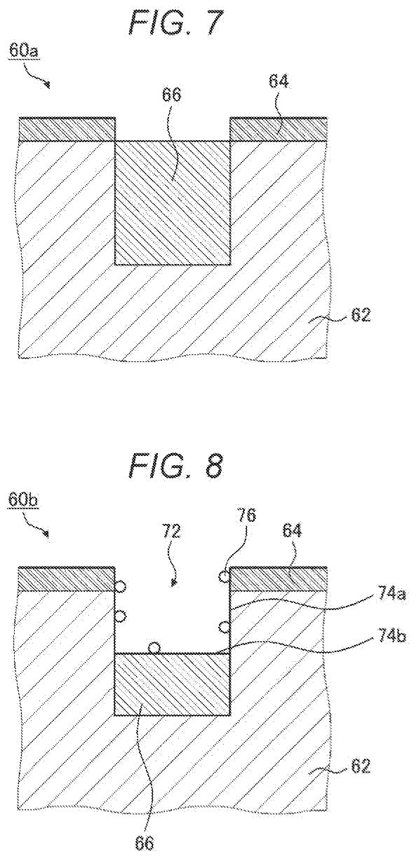

An object to be treated 60b shown in FIG. 8 is obtained by dry-etching the object to be treated before dry-etching shown in FIG. 7.

An object to be treated 60a shown in FIG. 7 has an insulating film 62 disposed on a substrate (not shown), a Ru-containing film 66 filled in a groove and the like formed in the insulating film 62, and a metal hard mask 64 in which the Ru-containing film 66 is located in an opening disposed on the insulating film 62. The object to be treated 60a is obtained by forming the insulating film 62 and the metal hard mask 64 in this order on the substrate (not shown), forming the groove and the like in the insulating film 62 located at an opening of the metal hard mask 64, filling the groove and the like with a Ru-containing substance to form the Ru-containing film 66.

When the object to be treated 60a shown in FIG. 7 is dry-etched, the Ru-containing film is etched, and the object to be treated 60b shown in FIG. 8 is obtained.

The object to be treated 60b shown in FIG. 8 has the insulating film 62 disposed on the substrate (not shown), the Ru-containing film 66 filled in a part of the groove and the like 72 formed in the insulating film 62, and the metal hard mask 64 disposed on the insulating film 62 and having an opening at the position of the groove and the like 72. Dry etching residues 76 adhere to a cross-sectional wall 74a composed of the insulating film 62 and the metal hard mask 64 in the groove and the like 72 and a bottom wall 74b composed of the Ru-containing film 66.

The dry etching residue contains a Ru-containing substance.

In addition, a W-containing substance (not shown) is present in the object to be treated 60b.

The Ru-containing film of the object to be treated, which is provided in step A4, preferably contains a simple substance of Ru, an alloy of Ru, an oxide of Ru, a nitride of Ru, or an oxynitride of Ru.

The Ru-containing substance of the object to be treated, which is provided in step A4, preferably contains a simple substance of Ru, an alloy of Ru, an oxide of Ru, a nitride of Ru, or an oxynitride of Ru.

A known material is selected for the interlayer insulating film and the insulating film.

A known material is selected for the metal hard mask.

Although aspects in which a metal hard mask is used have been described in FIGS. 6, 7, and 8, a resist mask formed using a known photoresist material may also be used.

Specific examples of the method of step A4 include a method of bringing the composition into contact with an object to be treated.

The method for bringing the composition into contact with the wiring board is as described above.

Suitable ranges of the contact time between the composition and the wiring board, and the temperature of the composition are as described above.

The W-containing substance is not removed in step A4.

### (Step A5)

Examples of step A include step A5 of removing a Ru-containing substance on a substrate which has been subjected to chemical mechanical polishing (CMP), by using the composition.

The CMP technique has been introduced into the planarization of an insulating film, the planarization of a connection hole, the production process of damascene wiring, and the like. The substrate after CMP may be contaminated by particles used for polishing, metal impurities, and the like. Therefore, it is necessary to remove these contaminants and wash the substrate before the next processing stage starts. By performing step A5, it is possible to remove the Ru-containing substance which is generated and adheres onto the substrate in a case where the object to be treated by CMP has Ru-containing wiring or in a case where the object to be treated by CMP has a Ru-containing film.

Examples of the object to be treated in step A5 include a substrate having a Ru-containing substance after CMP as described above.

The Ru-containing substance preferably contains a simple substance of Ru, an alloy of Ru, an oxide of Ru, a nitride of Ru, or an oxynitride of Ru.

A W-containing substance is present in the substrate having a Ru-containing substance after CMP.

Specific examples of the method of step A5 include a method of bringing the composition into contact with an object to be treated.

The method for bringing the composition into contact with the wiring board is as described above.

Suitable ranges of the contact time between the composition and the wiring board, and the temperature of the composition are as described above.

The W-containing substance is not removed in step A5.

### (Step A6)

Examples of step A include step A6 of removing, by using the composition, a Ru-containing substance in a region other than a Ru-containing film formation region on a substrate on which a Ru-containing film has been deposit in the Ru-containing film formation region. As described above, the method for forming a Ru-containing film is not particularly limited, and the Ru-containing film can be formed on the substrate by sputtering, CVD, MBE, and ALD.

When the Ru-containing film is formed in the Ru-containing film formation region (region where the Ru-containing film is to be formed) on the substrate by the above-described method, the Ru-containing film may also be formed in an unintended portion (region other than the Ru-containing film formation region). Examples of the unintended portion include the side wall of the insulating film in the filling of the Ru-containing film in a groove and the like provided in the insulating film.

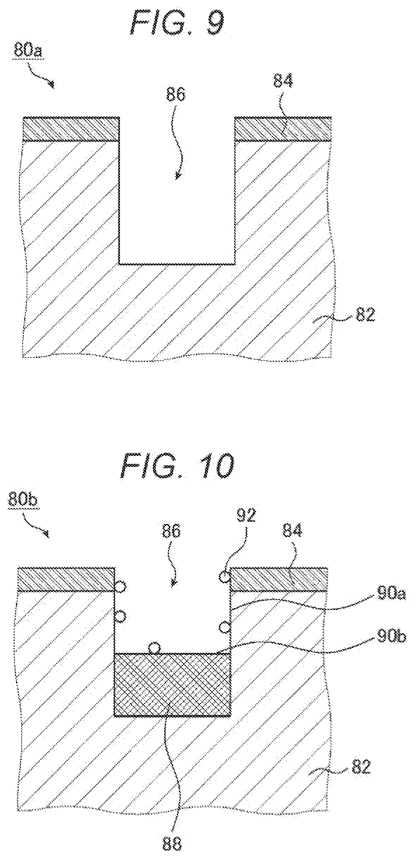

FIG. 10 shows an example of the object to be treated in step A6. An object to be treated 80b shown in FIG. 10 is obtained by forming a Ru-containing film on the object to be treated 80a on which the Ru-containing film is not formed, as shown in FIG. 9.

The object to be treated 80a shown in FIG. 9 has an insulating film 82 disposed on a substrate (not shown) and a metal hard mask 84 disposed on the insulating film 82. The insulating film 82 has a groove and the like 86 at the position of the opening of the metal hard mask 84. By forming the Ru-containing film so as to fill a part of the groove and the like 86 of the object to be treated 80a, the object to be treated 80b shown in FIG. 10 is obtained.

The object to be treated 80b shown in FIG. 10 has the insulating film 82 disposed on a substrate (not shown), a Ru-containing film 88 filled in a part of the groove and the like 86 formed in the insulating film 82, and the metal hard mask 84 disposed on the insulating film 82 and having an opening at the position of the groove and the like 86. Residues 92 in the formation of the Ru-containing film adhere to a cross-sectional wall 90a composed of the insulating film 82 and the metal hard mask 84 in the groove and the like 86 and a bottom wall 90b composed of the Ru-containing film 88.

In the above-described aspect, a region where the Ru-containing film 88 is located corresponds to the Ru-containing film formation region, and the cross-sectional wall 90a and the bottom wall 90b correspond to the region other than the Ru-containing film formation region.

In addition, a W-containing substance (not shown) is present in the object to be treated 80b.

The Ru-containing film preferably contains a simple substance of Ru, an alloy of Ru, an oxide of Ru, a nitride of Ru, or an oxynitride of Ru.

The Ru-containing substance preferably contains a simple substance of Ru, an alloy of Ru, an oxide of Ru, a nitride of Ru, or an oxynitride of Ru.

A known material is selected for the metal hard mask.

Although aspects in which a metal hard mask is used have been described in FIGS. 9 and 10, a resist mask formed using a known photoresist material may also be used.

Specific examples of the method of step A6 include a method of bringing the composition into contact with an object to be treated.

The method for bringing the composition into contact with the wiring board is as described above.

Suitable ranges of the contact time between the composition and the wiring board, and the temperature of the composition are as described above.

The W-containing substance is not removed in step A6.

### [Step C]

The present treatment process may include, as necessary after step A, step C of performing a rinsing treatment on the substrate obtained by step Aby using a rinsing liquid.

Preferred examples of the rinsing liquid include hydrofluoric acid (preferably 0.001 to 1 mass % hydrofluoric acid), hydrochloric acid (preferably 0.001 to 1 mass % hydrochloric acid), aqueous hydrogen peroxide (preferably 0.5 to 31 mass % aqueous hydrogen peroxide, more preferably 3 to 15 mass % aqueous hydrogen peroxide), a mixed solution (FPM) of hydrofluoric acid and aqueous hydrogen peroxide, a mixed solution (SPM) of sulfuric acid and aqueous hydrogen peroxide, a mixed solution (APM) of aqueous ammonia and aqueous hydrogen peroxide, a mixed solution (HPM) of hydrochloric acid and aqueous hydrogen peroxide, aqueous carbon dioxide (preferably 10 to 60 ppm by mass aqueous carbon dioxide), aqueous ozone (preferably 10 to 60 ppm by mass aqueous ozone), aqueous hydrogen (preferably 10 to 20 ppm by mass aqueous hydrogen), an aqueous citric acid solution (preferably 0.01 to 10 mass % aqueous citric acid solution), acetic acid (preferably acetic acid stock solution or 0.01 to 10 mass % aqueous acetic acid solution), sulfuric acid (preferably 1 to 10 mass % aqueous sulfuric acid solution), aqueous ammonia (preferably 0.01 to 10 mass % aqueous ammonia), isopropyl alcohol (IPA), an aqueous hypochlorous acid solution (preferably 1 to 10 mass % aqueous hypochlorous acid solution), aqua regia (preferably aqua regia corresponding to a formulation of 2.6/1.4 to 3.4/0.6 as a volume ratio of 37 mass % hydrochloric acid to 60 mass % nitric acid), ultrapure water, nitric acid (preferably 0.001 to 1 mass % nitric acid), perchloric acid (preferably 0.001 to 1 mass % perchloric acid), an aqueous oxalic acid solution (preferably 0.01 to 10 mass % aqueous oxalic acid solution), and an aqueous periodic acid solution (preferably 0.5 to 10 mass % aqueous periodic acid solution, and the periodic acid is, for example, orthoperiodic acid and metaperiodic acid).

Preferred conditions for FPM, SPM, APM, and HPM are, for example, the same as the suitable forms for FPM, SPM, APM, and HPM used as the specific solution described above.

Hydrofluoric acid, nitric acid, perchloric acid, and hydrochloric acid respectively mean aqueous solutions obtained by dissolving HF, HNO₃, HClO4, and HCl in water.

The aqueous ozone, aqueous carbon dioxide, and aqueous hydrogen respectively mean aqueous solutions obtained by dissolving 03, CO₂, and H₂ in water.

These rinsing liquids may be used by being mixed together as long as the purpose of the rinsing step is not impaired.

Among these, as the rinsing liquid, from the viewpoint of further reducing residual chlorine on the substrate surface after the rinsing step, aqueous carbon dioxide, aqueous ozone, aqueous hydrogen, hydrofluoric acid, an aqueous citric acid solution, hydrochloric acid, sulfuric acid, aqueous ammonia, aqueous hydrogen peroxide, SPM, APM, HPM, IPA, an aqueous hypochlorous acid solution, aqua regia, or FPM is preferable, and hydrofluoric acid, hydrochloric acid, aqueous hydrogen peroxide, SPM, APM, HPM, or FPM is more preferable.

Examples of the specific method of step C include a method of bringing the rinsing liquid into contact with the substrate obtained by step A, which is an object to be treated.

Examples of the method for bringing the rinsing liquid into contact with the substrate include a method of immersing the substrate in the rinsing liquid charged in a tank, a method of spraying the rinsing liquid onto the substrate, a method of causing the rinsing liquid to flow onto the substrate, and a combination thereof.

The treatment time (the contact time between the rinsing liquid and the object to be treated) is not particularly limited, and is, for example, 5 seconds to 5 minutes. he temperature of the rinsing liquid during the treatment is not particularly limited, but is generally preferably 16 to 60° C. and more preferably 18 to 40° C. In a case where SPM is used as the rinsing liquid, the temperature of the SPM is preferably 90 to 250° C.

### [Step D]

The present treatment method may include step D of performing a drying treatment, as necessary after step C.

The method of the drying treatment is not particularly limited, and examples thereof include spin drying, flowing of a drying gas on the substrate, means for heating the substrate (for example, heating with a hot plate or an infrared lamp), isopropyl alcohol (IPA) vapor drying, Marangoni drying, Rotagoni drying, and a combination thereof.

The drying time can be appropriately changed depending on the specific method used, and is, for example, about 30 seconds to several minutes.

### [Other Steps]

The present treatment method may be performed in combination before or after other steps performed on the substrate. The present treatment method may be incorporated into other steps while the treatment method according to an embodiment of the present invention is performed, or the present treatment method may be incorporated into other steps.

Examples of the other steps include a formation step of forming structures such as metal wiring, a gate structure, a source structure, a drain structure, an insulating film, a ferromagnetic layer, a non-magnetic layer, and the like (for example, layer formation, etching, chemical mechanical polishing, and modification), a resist formation step, an exposure step and a removal step, a heat treatment step, a washing step, and an inspection step.

The present treatment method may be performed at any stage of the back end of the line (BEOL), the middle of the line (MOL), and the front end of the line (FEOL), and is preferably performed in the front end of the line or the middle of the line.

### Example

Hereinafter, the present invention will be described in more detail based on Examples. Materials, used amounts, ratios, treatment contents, treatment procedures, and the like shown in the following Examples can be suitably modified without departing from the scope of the present invention.

Accordingly, the scope of the present invention should not be interpreted in a limited way by Examples to be described below.

### <Preparation of Composition>

Ultrapure water and each component were mixed so as to have the contents shown in Table 1 below to obtain a mixed solution. Then, the mixed solution was thoroughly stirred with a stirrer to obtain a composition used in each of Examples and Comparative Examples.

The content of the composition in Table 1 is based on mass, and the remainder of the total of the components is water.

Hereinafter, the components listed in Table 1 below are specifically shown.

### [Periodic Acid or Salt Thereof]

IO-1: Orthoperiodic acid
IO-2: Sodium orthoperiodate
IO-3: Metaperiodic acid

### [Quaternary Ammonium Salt]

A-1: Tetramethylammonium hydroxide
B-1: Tetraethyl ammonium hydroxide
B-2: Tetraethyl ammonium chloride
B-3: Tetraethyl ammonium bromide
B-4: Tetraethyl ammonium fluoride
C-1: Tetrabutylammonium hydroxide
D-1: Ethyltrimethylammonium hydroxide
D-2: Ethyltrimethylammonium chloride
E-1: Diethyldimethylammonium hydroxide
F-1: Triethylmethylammonium hydroxide
G-1: (2-hydroxyethyl)trimethylammonium hydroxide
H-1: Tributylmethylammonium hydroxide
I-1: Dimethyldipropylammonium hydroxide
J-1: Benzyltrimethylammonium hydroxide
K-1: Benzyltriethylammonium hydroxide
L-1: Triethyl(2-hydroxyethyl)ammonium hydroxide
M-1: Dodecyltrimethylammonium hydroxide
N-1: Tetradecyltrimethylammonium hydroxide
O-1: Hexadecyltrimethylammonium hydroxide

### [Nitrogen-Containing Resin]

As the nitrogen-containing resin, the following compounds were used.

The weight average molecular weight of each compound is as shown in Table 1 below.
PA-1 to PA-9: Compounds containing repeating units represented by the following formulae

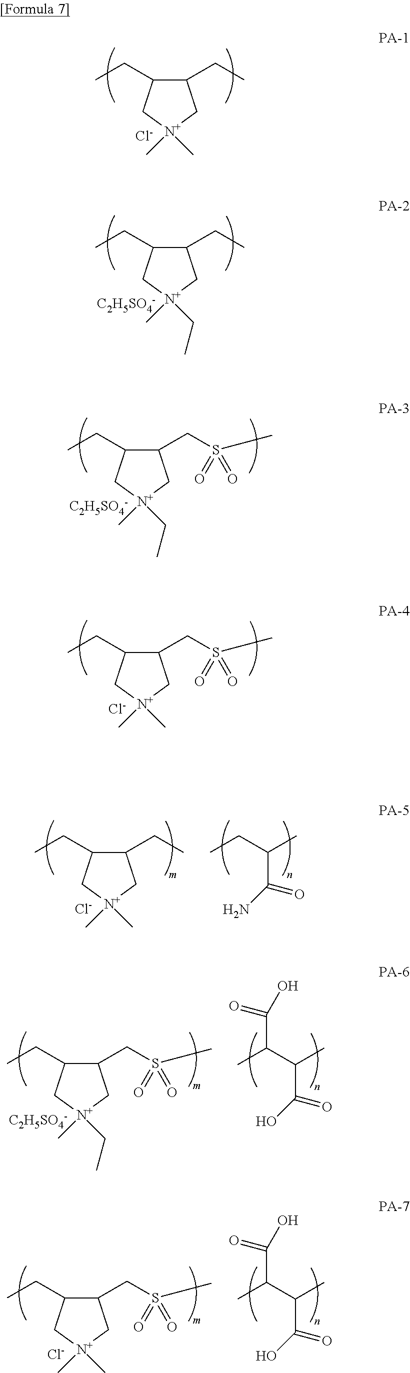

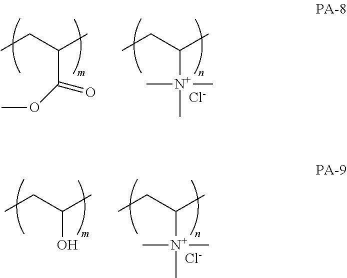

PB-1 to PB-4: Compounds containing repeating units represented by the following formulae

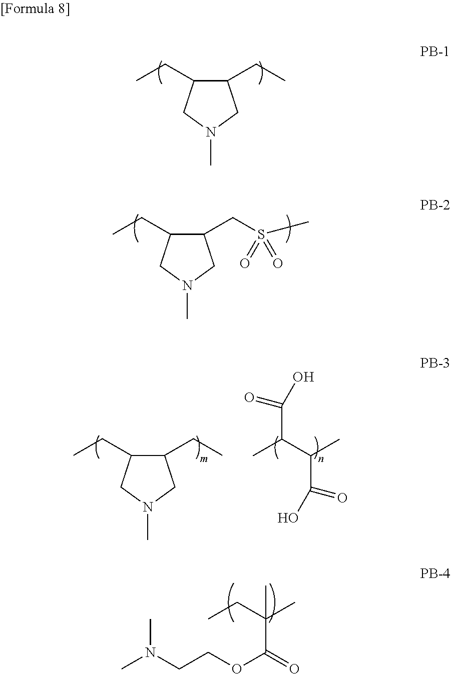

PC-1 and PC-2: Compounds containing repeating units represented by the following formulae

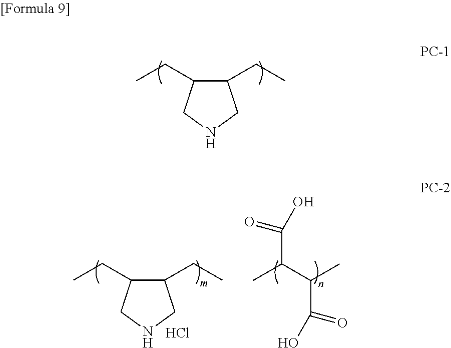

PD-1 and PD-2: Compounds containing repeating units represented by the following formulae

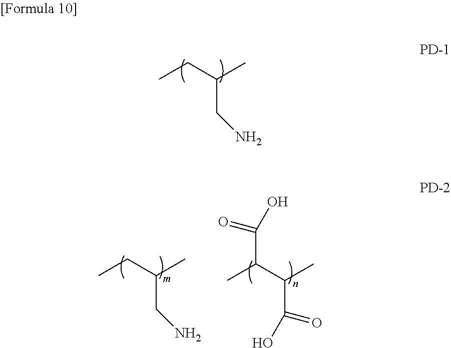

PE-1 to PE-3: Compounds containing repeating units represented by the following formulae

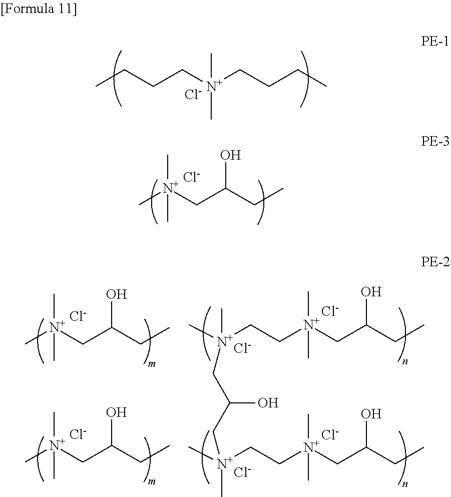

PF-1 and PF-2: Compounds containing repeating units represented by the following formulae

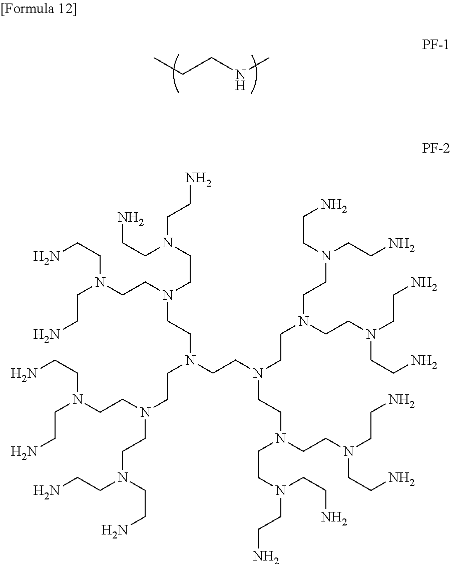

### [Water]

Ultrapure water

### [Additives]

Additives used in Example 71, Example 72, and Comparative Example 4 are as follows.
IA: Iodic acid
TEA: Triethylamine
BMPC: 1-Butyl-1-methylpyrrolidinium chloride

### <Evaluation>

The ratio (ERR (Ru/W)) of the etching rate for Ru (ERRu) to the etching rate for W (ERW) by the composition, that is, the Ru/W selectivity was evaluated according to the following procedure.

A substrate was prepared by forming a Ru layer (layer formed of a simple substance of Ru) on one surface of a commercially available silicon wafer (diameter: 12 inches) by PVD.

The obtained substrate was placed in a container filled with a 1 mass % aqueous citric acid solution, and the aqueous citric acid solution was stirred to perform a pretreatment.

The pretreated substrate was placed in a container filled with the composition of each of Examples or Comparative Examples, and the composition was stirred to perform a removal treatment of the Ru layer for 1 minute. The temperature of the composition was 25° C.

The thicknesses of the Ru layer before and after the removal treatment were measured with an X-ray fluorescence spectrometer for thin film evaluation (XRF AZX-400, manufactured by Rigaku Corporation), and the etching rate for the Ru layer (ERRu A/min) was calculated from the difference in the thickness of the Ru layer before and after the removal treatment.

The removal treatment of the W layer was performed in the same manner as the above-described procedure, except that the W layer (layer formed of a simple substance of W) was formed by CVD. The thicknesses of the W layer before and after the removal treatment were obtained using a resistivity measurement system (VR300DE, manufactured by Kokusai Electric Semiconductor Service Inc.). The etching rate for the W layer (ERW Amin) was calculated from the obtained thicknesses of the W layer.

The ratio (ERR (Ru/W)) of ERRu to ERW was obtained by dividing ERRu calculated by the above-described method by ERW. The Ru/W selectivity was evaluated based on the obtained ERR (Ru/W) according to the following criteria.

### [Evaluation Criteria for ERR (Ru/W)]

A: 30.0 or more
B: 10.0 or more and less than 30.0
C: 5.0 or more and less than 10.0
D: 2.0 or more and less than 5.0
E: 0.0 or more and less than 2.0

### <Results>

The formulation of the composition and the evaluation results are shown by dividing Table 1 into Tables 1-1, 1-2, and 1-3.

In the table, the “content” of each component represents a content (mass % or ppm by mass) with respect to the total mass of the composition. The remainder of the total content of each of components is water.

In the table, in Examples in which a plurality of types of components are listed in one Example, the plurality of types of components were added at the contents shown in the table.

In the table, the “molecular weight” of the nitrogen-containing resin represents the weight average molecular weight calculated by GPC.

In the table, the “pH” indicates a value obtained by measuring the pH of the composition with a pH meter (F-51 (trade name) manufactured by Horiba, Ltd.).

The measurement temperature was 25° C.

TABLE 1

| | Periodic acid | | Quaternary | | | | | | | | | |
|---|---|---|---|---|---|---|---|---|---|---|---|---|
| | or salt thereof | | ammonium salt | | Nitrogen-containing resin | | | | | | | |
| | | Content | | Content | | Molecular | Content | | | | | |
| Table 1-1 | Type | (mass %) | Type | (mass %) | Type | weight | (ppm by mass) | pH | RuER | WER | Ru/W | Evaluation |
| Example 1 | IO-1 | 2.00 | B-1 | 1.00 | PA-1 | 3000 | 25 | 6.5 | 187 | 6.5 | 28.8 | B |
| Example 2 | IO-1 | 2.00 | D-1 | 1.00 | PA-2 | 5000 | 25 | 6.2 | 188 | 8.0 | 23.5 | B |
| Example 3 | IO-1 | 2.00 | B-1 | 1.00 | PA-3 | 6000 | 25 | 6.5 | 160 | 13.0 | 12.3 | B |
| Example 4 | IO-1 | 2.00 | D-1 | 1.00 | PA-4 | 2000 | 25 | 6.3 | 145 | 11.0 | 13.2 | B |
| Example 5 | IO-1 | 2.00 | B-1 | 1.00 | PA-5 | 2500 | 25 | 6.4 | 132 | 9.0 | 14.7 | B |
| Example 6 | IO-1 | 2.00 | D-1 | 1.00 | PA-6 | 7000 | 25 | 6.8 | 175 | 10.0 | 17.5 | B |
| Example 7 | IO-1 | 2.00 | B-1 | 1.00 | PA-7 | 2000 | 25 | 6.5 | 155 | 8.0 | 19.4 | B |
| Example 8 | IO-1 | 2.00 | D-1 | 1.00 | PA-8 | 3000 | 25 | 6.9 | 180 | 10.0 | 18.0 | B |
| Example 9 | IO-1 | 2.00 | B-1 | 1.00 | PA-9 | 5000 | 25 | 6.7 | 175 | 11.0 | 15.9 | B |
| Example 10 | IO-1 | 2.00 | D-1 | 1.00 | PB-1 | 10000 | 25 | 6.1 | 164 | 18.0 | 9.1 | C |
| Example 11 | IO-1 | 2.00 | B-1 | 1.00 | PB-1 | 5000 | 25 | 6.0 | 163 | 18.0 | 9.1 | C |
| Example 12 | IO-1 | 2.00 | D-1 | 1.00 | PB-1 | 6000 | 25 | 6.2 | 165 | 20.0 | 8.3 | C |
| Example 13 | IO-1 | 2.00 | B-1 | 1.00 | PB-1 | 3000 | 25 | 6.5 | 155 | 17.0 | 9.1 | C |
| Example 14 | IO-1 | 2.00 | D-1 | 1.00 | PB-2 | 7500 | 25 | 6.4 | 152 | 25.0 | 6.1 | C |
| Example 15 | IO-1 | 2.00 | B-1 | 1.00 | PB-3 | 6000 | 25 | 6.1 | 170 | 26.0 | 6.5 | C |
| Example 16 | IO-1 | 2.00 | D-1 | 1.00 | PB-4 | 5000 | 25 | 6.2 | 132 | 16.0 | 8.3 | C |
| Example 17 | IO-1 | 2.00 | B-1 | 1.00 | PC-1 | 10000 | 25 | 6.3 | 75 | 15.0 | 5.0 | C |
| Example 18 | IO-1 | 2.00 | D-1 | 1.00 | PC-2 | 9000 | 25 | 6.7 | 52 | 23.0 | 2.3 | D |
| Example 19 | IO-1 | 2.00 | B-1 | 1.00 | PC-1 | 3000 | 25 | 6.2 | 105 | 26.0 | 4.0 | D |
| Example 20 | IO-1 | 2.00 | D-1 | 1.00 | PD-1 | 2000 | 25 | 6.5 | 64 | 19.0 | 3.4 | D |
| Example 21 | IO-1 | 2.00 | B-1 | 1.00 | PD-1 | 4000 | 25 | 6.8 | 80 | 20.0 | 4.0 | D |
| Example 22 | IO-1 | 2.00 | D-1 | 1.00 | PD-2 | 5000 | 25 | 6.9 | 92 | 35.0 | 2.6 | D |
| Example 23 | IO-1 | 2.00 | B-1 | 1.00 | PE-1 | 6500 | 25 | 6.4 | 177 | 4.5 | 39.3 | A |
| Example 24 | IO-1 | 2.00 | D-1 | 1.00 | PE-2 | 7000 | 25 | 6.3 | 160 | 4.3 | 37.2 | A |
| Example 25 | IO-1 | 2.00 | D-1 | 1.00 | PE-3 | 3000 | 25 | 6.8 | 132 | 2.5 | 52.8 | A |
| Example 26 | IO-1 | 2.00 | B-1 | 1.00 | PF-1 | 8000 | 25 | 6.0 | 87 | 19.0 | 4.6 | D |
| Example 27 | IO-1 | 2.00 | D-1 | 1.00 | PF-2 | 2000 | 25 | 6.1 | 96 | 15.0 | 6.4 | C |
| Example 28 | IO-1 | 2.00 | D-1 | 1.00 | PE-3 | 650 | 25 | 6.4 | 182 | 42.0 | 4.3 | D |
| Example 29 | IO-1 | 2.00 | B-1 | 1.00 | PE-3 | 1500 | 25 | 6.4 | 165 | 5.0 | 33.0 | A |
| Example 30 | IO-1 | 2.00 | D-1 | 1.00 | PE-3 | 6000 | 25 | 6.3 | 150 | 3.5 | 42.9 | A |
| Example 31 | IO-1 | 2.00 | B-1 | 1.00 | PE-3 | 10000 | 25 | 6.6 | 132 | 7.5 | 17.6 | B |
| Example 32 | IO-1 | 2.00 | D-1 | 1.00 | PE-3 | 20000 | 25 | 6.8 | 125 | 10.0 | 12.5 | B |
| Example 33 | IO-1 | 2.00 | B-1 | 1.00 | PE-3 | 50000 | 25 | 6.1 | 105 | 12.0 | 8.8 | C |
| Example 34 | IO-1 | 2.00 | D-1 | 1.00 | PE-3 | 100000 | 25 | 6.6 | 112 | 15.0 | 7.5 | C |
| Example 35 | IO-1 | 2.00 | B-1 | 1.00 | PE-3 | 170000 | 25 | 6.8 | 95 | 19.0 | 5.0 | C |
| Example 36 | IO-1 | 2.00 | B-1 | 1.00 | PE-3 | 250000 | 25 | 6.1 | 65 | 22.0 | 3.0 | D |
| Example 37 | IO-1 | 2.00 | D-1 | 0.20 | PE-2 | 7000 | 25 | 1.5 | 32 | 9.5 | 3.4 | D |
| Example 38 | IO-1 | 2.00 | B-1 | 0.50 | PE-2 | 7000 | 25 | 3.2 | 105 | 6.5 | 16.2 | B |
| Example 39 | IO-1 | 2.00 | D-1 | 0.78 | PE-2 | 7000 | 25 | 4.5 | 145 | 4.5 | 32.2 | A |
| Example 40 | IO-1 | 2.00 | D-1 | 1.20 | PE-2 | 7000 | 25 | 7.5 | 155 | 4.2 | 36.9 | A |

TABLE 2

| | Periodic acid | | Quaternary | | | | | | | | | |
|---|---|---|---|---|---|---|---|---|---|---|---|---|
| | or salt thereof | | ammonium salt | | Nitrogen-containing resin | | | | | | | |
| | | Content | | Content | | Molecular | Content | | | | | |
| Table 1-2 | Type | (mass %) | Type | (mass %) | Type | weight | (ppm by mass) | pH | RuER | WER | Ru/W | Evaluation |
| Example 41 | IO-1 | 2.00 | B-1 | 1.70 | PE-2 | 7000 | 25 | 8.0 | 98 | 3.5 | 28.0 | B |
| Example 42 | IO-1 | 2.00 | D-1 | 2.00 | PE-2 | 7000 | 25 | 10.5 | 85 | 9.0 | 9.4 | C |
| Example 43 | IO-1 | 2.00 | B-1 | 2.50 | PE-2 | 7000 | 25 | 12.0 | 45 | 20.0 | 2.3 | D |
| Example 44 | IO-2 | 2.00 | B-1 | 1.00 | PA-1 | 3000 | 25 | 6.3 | 165 | 7.0 | 23.6 | B |
| Example 45 | IO-3 | 2.00 | B-1 | 1.00 | PA-1 | 3000 | 25 | 6.4 | 175 | 6.0 | 29.2 | B |
| Example 46 | IO-1 | 2.00 | A-1 | 1.00 | PE-3 | 3000 | 25 | 6.8 | 132 | 3.0 | 44.0 | A |
| Example 47 | IO-1 | 2.00 | C-1 | 1.00 | PE-3 | 3000 | 25 | 6.5 | 105 | 3.8 | 27.6 | B |
| Example 48 | IO-1 | 2.00 | E-1 | 1.00 | PE-3 | 3000 | 25 | 6.7 | 145 | 4.5 | 32.2 | A |
| Example 49 | IO-1 | 2.00 | F-1 | 1.00 | PE-3 | 3000 | 25 | 6.2 | 120 | 4.0 | 30.0 | A |
| Example 50 | IO-1 | 2.00 | G-1 | 1.00 | PE-3 | 3000 | 25 | 6.1 | 150 | 3.5 | 42.9 | A |
| Example 51 | IO-1 | 2.00 | H-1 | 1.00 | PE-3 | 3000 | 25 | 6.2 | 135 | 3.7 | 36.5 | A |
| Example 52 | IO-1 | 2.00 | I-1 | 1.00 | PE-3 | 3000 | 25 | 6.5 | 143 | 4.5 | 31.8 | A |
| Example 53 | IO-1 | 2.00 | J-1 | 1.00 | PE-3 | 3000 | 25 | 6.3 | 130 | 4.2 | 31.0 | A |
| Example 54 | IO-1 | 2.00 | K-1 | 1.00 | PE-3 | 3000 | 25 | 6.4 | 147 | 3.6 | 40.8 | A |
| Example 55 | IO-1 | 2.00 | L-1 | 1.00 | PE-3 | 3000 | 25 | 6.8 | 150 | 3.1 | 48.4 | A |
| Example 56 | IO-1 | 2.00 | M-1 | 1.00 | PE-3 | 3000 | 25 | 6.5 | 98 | 15.0 | 6.5 | C |
| Example 57 | IO-1 | 2.00 | N-1 | 1.00 | PE-3 | 3000 | 25 | 6.4 | 102 | 19.0 | 5.4 | C |
| Example 58 | IO-1 | 2.00 | O-1 | 1.00 | PE-3 | 3000 | 25 | 6.1 | 85 | 14.0 | 6.1 | C |
| Example 59 | IO-1 | 2.00 | B-2 | 1.00 | PE-3 | 3000 | 25 | 6.2 | 137 | 5.1 | 26.9 | B |
| Example 60 | IO-1 | 2.00 | D-2 | 1.00 | PE-3 | 3000 | 25 | 6.4 | 140 | 4.8 | 29.2 | B |
| Example 61 | IO-1 | 2.00 | B-3 | 1.00 | PE-3 | 3000 | 25 | 6.8 | 120 | 17.0 | 7.1 | C |
| Example 62 | IO-1 | 2.00 | B-4 | 1.00 | PE-3 | 3000 | 25 | 6.5 | 135 | 16.0 | 8.4 | C |
| Example 63 | IO-1 | 2.00 | B-1 | 1.00 | PE-1 | 3000 | 0.1 | 6.6 | 204 | 29.0 | 7.0 | C |
| Example 64 | IO-1 | 2.00 | D-1 | 1.00 | PE-1 | 3000 | 5 | 6.9 | 201 | 6.0 | 33.5 | A |
| Example 65 | IO-1 | 2.00 | B-1 | 1.00 | PE-1 | 3000 | 200 | 6.2 | 165 | 5.4 | 30.6 | A |
| Example 66 | IO-1 | 2.00 | D-1 | 1.00 | PE-1 | 3000 | 800 | 6.3 | 158 | 7.2 | 21.9 | B |
| Example 67 | IO-1 | 2.00 | D-1 | 1.00 | PE-1 | 3000 | 1500 | 6.1 | 72 | 11.0 | 6.5 | C |
| Example 68 | IO-1 | 0.20 | D-1 | 0.10 | PE-2 | 7000 | 5 | 6.5 | 24 | 0.8 | 30.0 | A |
| Example 69 | IO-1 | 1.00 | D-1 | 0.50 | PE-2 | 7000 | 15 | 6.4 | 89 | 2.5 | 35.6 | A |
| Example 70 | IO-1 | 5.00 | D-1 | 2.40 | PE-2 | 7000 | 100 | 6.3 | 268 | 7.5 | 35.7 | A |
| Example 71 | IO-1 | 2.00 | B-1 | 1.00 | PA-1 | 3000 | 10 | 6.9 | 137 | 2.5 | 54.8 | A |
| | | | | | PE-2 | 7000 | 15 | | | | | |
| Example 72 | IO-1 | 2.00 | B-1 | 1.00 | PA-1 | 3000 | 20 | 6.2 | 156 | 4.2 | 37.1 | A |
| | | | | | PE-3 | 3000 | 5 | | | | | |
| Example 73 | IO-1 | 2.00 | B-1 | 0.50 | PA-1 | 3000 | 25 | 6.2 | 170 | 6.5 | 26.2 | B |
| | | | D-1 | 0.50 | | | | | | | | |
| Example 74 | IO-1 | 2.00 | B-1 | 0.50 | PE-3 | 7000 | 25 | 6.2 | 145 | 3.7 | 39.2 | A |
| | | | E-1 | 0.50 | | | | | | | | |
| Comparative | IO-1 | 2.00 | B-1 | 1.00 | — | — | — | 6.2 | 227 | 199.0 | 1.1 | E |
| Example 1 | | | | | | | | | | | | |
| Comparative | — | — | B-1 | 1.00 | PF-1 | 3000 | 25 | 11.7 | 0.1 | 15.0 | 0.01 | E |
| Example 2 | | | | | | | | | | | | |
| Comparative | IO-1 | 2.00 | — | — | PF-1 | 3000 | 25 | 2.7 | 21 | 35.0 | 0.6 | E |
| Example 3 | | | | | | | | | | | | |

TABLE 3

| | Periodic acid | | Quaternary | | Nitrogen-containing resin | | | Additive | | | | | | |
|---|---|---|---|---|---|---|---|---|---|---|---|---|---|---|
| | or salt thereof | | ammonium salt | | | | Content | | Content | | | | | |
| | | Content | | Content | | Molecular | (ppm by | | (ppm by | | | | | |
| Table 1-3 | Type | (mass %) | Type | (mass %) | Type | weight | mass) | Type | mass) | pH | RuER | WER | Ru/W | Evaluation |
| Example 75 | IO-1 | 2.00 | B-1 | 1.00 | PE-1 | 6500 | 25 | IA | 10 | 6.8 | 165 | 4.2 | 39.3 | A |
| Example 76 | IO-1 | 2.00 | B-1 | 1.00 | PE-1 | 6500 | 25 | TEA | 10 | 6.8 | 179 | 4.7 | 38.1 | A |
| Comparative | IO-1 | 2.00 | B-1 | 1.00 | — | — | — | BMPC | 10000 | 6.4 | 182 | 168.0 | 1.1 | E |
| Example 4 | | | | | | | | | | | | | | |

From the results in Table 1, it was confirmed that the composition according to an embodiment of the present invention has excellent Ru/W selectivity.

From the comparison between Examples 10 to 22, 26, and 27 and Examples 1 to 9, 23 to 25, and 71 to 76, it was confirmed that in a case where the nitrogen-containing resin had a quaternary ammonium salt structure, the Ru/W selectivity was more excellent.

From the comparison between Examples 1 to 9 and 73 and Examples 23 to 25, 71, 72, and 74 to 76, it was confirmed that in a case where the nitrogen-containing resin contained a nitrogen atom in the main chain, the Ru/W selectivity was more excellent.

From the comparison between Examples 56 to 58 and Examples 23 to 25, 46 to 55, 59 to 62, and 71 to 76, it was confirmed that in a case where the quaternary ammonium salt included at least one selected from the group consisting of a tetramethylammonium salt, a tetraethyl ammonium salt, a tetrabutylammonium salt, an ethyltrimethylammonium salt, a triethylmethylammonium salt, a diethyldimethylammonium salt, a tributylmethylammonium salt, a dimethyldipropylammonium salt, a benzyltrimethylammonium salt, a benzyltriethylammonium salt, a (2-hydroxyethyl)trimethylammonium salt, and a triethyl(2-hydroxyethyl)ammonium salt, the Ru/W selectivity was more excellent.

From the comparison between Examples 37, 42, and 43 and Examples 38 to 41, it was confirmed that in a case where the pH was 3.0 to 10.0, the Ru/W selectivity was more excellent.

From the comparison between Examples 28 and 36 and Examples 29 to 35, it was confirmed that in a case where the weight average molecular weight of the nitrogen-containing resin was 1,000 to 200,000, the Ru/W selectivity was more excellent.

From the comparison between Examples 63 and 67 and Examples 64 to 66, it was confirmed that in a case where the content of the nitrogen-containing resin was 1 to 1,000 ppm by mass with respect to the total mass of the composition, the Ru/W selectivity was more excellent.

### <Purification Treatment>

In addition, purification treatments of the following methods 1 to 6 were respectively performed on the compositions of Examples 1 to 76, to obtain 500 g of purification treatment compositions. The same evaluation as described above was performed on each of the purification treatment compositions, and the same evaluation results as the results in each of Examples were obtained.

### [Method 1]

ORLITE DS-4 (75 ml) manufactured by Organo Corporation, as a cation exchange resin, was packed in a column (internal volume: 300 ml) set vertically. The composition was passed through the column at a space velocity (SV) of 1.4 (1/h). In a series of operations, all of the cation exchange resin, the composition, and the like were kept at a temperature of 25° C.

### [Method 2]

ORLITE DS-21 (75 ml) manufactured by Organo Corporation, as a chelate resin, was packed in a column (internal volume: 300 ml) set vertically. The composition was passed through the column at a space velocity (SV) of 1.4 (1/h). In a series of operations, all of the chelate resin, the composition, and the like were kept at a temperature of 25° C.

### [Method 3]

A mixture of ORLITE DS-21 (75 ml) and DS-4 (75 ml) manufactured by Organo Corporation, as a mixed resin, was packed in a column (internal volume: 300 ml) set vertically. The composition was passed through the column at a space velocity (SV) of 1.4 (1/h). In a series of operations, all of the mixed resin, the composition, and the like were kept at a temperature of 25° C.

### [Method 4]

The composition was passed at 100 mL/min through an ion exchange resin membrane Mustang Q (0.02 m²) manufactured by Pall Corporation. In a series of operations, the temperature of the membranous ion exchanger, the composition, and the like was 25° C.

### [Method 5]

ORLITE DS-4 (75 ml) manufactured by Organo Corporation, as a cation exchange resin, was packed in a column (internal volume: 300 ml) set vertically. This column was used as a cation exchange column.

In addition, ORLITE DS-21 (75 ml) manufactured by Organo Corporation, as a chelate resin, was packed in a column (internal volume: 300 ml) set vertically. This column was used as a chelate resin column.

The composition was passed through the cation exchange column, and then passed through the chelate resin column. In both cases, the composition was passed at a space velocity (SV) of 1.4 (1/h). In a series of operations, all of the cation exchange resin, the chelate resin, the composition, and the like were kept at a temperature of 25° C.

### [Method 6]

The composition was passed through the chelate resin column of Method 5, and then passed through the cation exchange column of Method 5. In both cases, the composition was passed at a space velocity (SV) of 1.4 (1/h). In a series of operations, all of the cation exchange resin, the chelate resin, the composition, and the like were kept at a temperature of 25° C.

### EXPLANATION OF REFERENCES

10a, 10b: Ru wiring board
12: insulating film
14: barrier metal layer
16: Ru-containing wiring
18: recess portion
20a, 20b: Ru liner substrate
22: insulating film
24: Ru-containing liner
26: wiring portion
28: recess portion
30: object to be treated
32: substrate
34: Ru-containing film
36: outer edge portion
40: object to be treated
42: substrate
44: Ru-containing film
46: etching stop layer
48: interlayer insulating film
50: metal hard mask
52: groove and the like
54: inner wall
54a: cross-sectional wall
54b: bottom wall
56: dry etching residue
60a, 60b: object to be treated
62: insulating film
64: metal hard mask
66: Ru-containing film
72: groove and the like
74a: cross-sectional wall
74b: bottom portion
76: dry etching residue
80a, 80b: object to be treated
82: insulating film
84: metal hard mask
86: groove and the like
88: Ru-containing film
90a: cross-sectional wall
90b: bottom wall
92: residue

What is claimed is:

1. A composition comprising:
periodic acid or a salt thereof;
a quaternary ammonium salt;
a resin containing a nitrogen atom; and
a solvent.

2. The composition according to claim 1,
wherein the composition is used for an object to be treated containing ruthenium.

3. The composition according to claim 1,
wherein the resin has a repeating unit containing a nitrogen atom.

4. The composition according to claim 1,
wherein the resin has a repeating unit selected from the group consisting of a repeating unit represented by Formula (1), a repeating unit represented by Formula (2), a repeating unit represented by Formula (3), and a repeating unit represented by Formula (4), 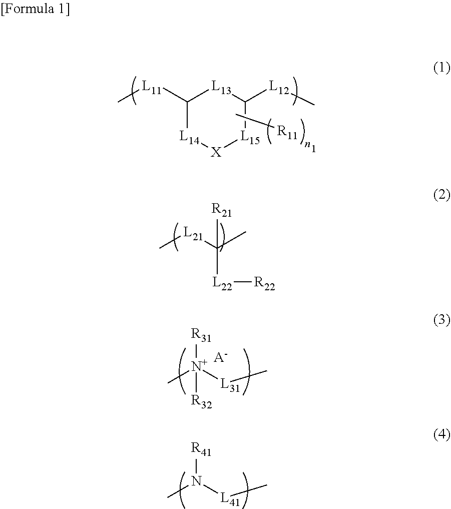
in Formula (1), L₁₁ to L₁₅ each independently represent a single bond or a divalent linking group,
X represents a divalent linking group containing a nitrogen atom,
R₁₁ each independently represents a monovalent substituent, and
n₁ represents an integer of 0 to 5,
in Formula (2), L₂₁ represents a divalent linking group,
L₂₂ represents a single bond or a divalent linking group,
R₂₁ represents a hydrogen atom or a monovalent substituent, and
R₂₂ represents a monovalent substituent containing a nitrogen atom,
in Formula (3), L₃₁ represents a divalent linking group,
R₃₁ and R₃₂ each independently represent a monovalent substituent, and
A⁻ represents a monovalent anion,
in Formula (4), L₄₁ represents a divalent linking group, and
R₄₁ represents a hydrogen atom or a monovalent substituent.

5. The composition according to claim 4,
wherein the resin has a repeating unit selected from the group consisting of the repeating unit represented by Formula (1), the repeating unit represented by Formula (2), and the repeating unit represented by Formula (3).

6. The composition according to claim 4,
wherein the resin has the repeating unit represented by Formula (1).

7. The composition according to claim 4,
wherein the resin has the repeating unit represented by Formula (3).

8. The composition according to claim 1,
wherein the resin has a repeating unit having a quaternary ammonium salt structure.

9. The composition according to claim 1,
wherein the resin has a nitrogen atom in a main chain.

10. The composition according to claim 1,
wherein the periodic acid or the salt thereof includes at least one selected from the group consisting of orthoperiodic acid, metaperiodic acid, and salts thereof.

11. The composition according to claim 1,
wherein the quaternary ammonium salt includes at least one selected from the group consisting of a tetramethylammonium salt, a tetraethyl ammonium salt, a tetrabutylammonium salt, an ethyltrimethylammonium salt, a triethylmethylammonium salt, a diethyldimethylammonium salt, a tributylmethylammonium salt, a dimethyldipropylammonium salt, a benzyltrimethylammonium salt, a benzyltriethylammonium salt, a (2-hydroxyethyl)trimethylammonium salt, and a triethyl(2-hydroxyethyl)ammonium salt.

12. The composition according to claim 1,
wherein the composition has a pH of 3.0 to 10.0.

13. The composition according to claim 1,
wherein a weight average molecular weight of the resin is 1,000 to 200,000.

14. The composition according to claim 1,
wherein a content of the resin is 1 to 1,000 ppm by mass with respect to a total mass of the composition.

15. The composition according to claim 1,
wherein the composition does not substantially contain insoluble particles.

16. A method for treating an object to be treated, comprising bringing an object to be treated containing ruthenium and tungsten into contact with the composition according to claim 1 to remove the ruthenium.

17. A method for treating an object to be treated, comprising bringing an object to be treated containing ruthenium and tungsten into contact with the composition according to claim 3 to remove the ruthenium.

18. A method for treating an object to be treated, comprising bringing an object to be treated containing ruthenium and tungsten into contact with the composition according to claim 4 to remove the ruthenium.

19. A method for treating an object to be treated, comprising bringing an object to be treated containing ruthenium and tungsten into contact with the composition according to claim 10 to remove the ruthenium.

20. A method for treating an object to be treated, comprising bringing an object to be treated containing ruthenium and tungsten into contact with the composition according to claim 11 to remove the ruthenium.
